(19) United States
(12) Patent Application Publication
(10) Pub. No.: US 2024/0422961 A1
(43) Pub. Date: Dec. 19, 2024

(54) SEMICONDUCTOR MEMORY DEVICE

(71) Applicant: Samsung Electronics Co., Ltd., Suwon-si (KR)

(72) Inventors: Joongchan SHIN, Suwon-si (KR); Seokhan PARK, Suwon-si (KR); Kiseok LEE, Suwon-si (KR); Moonyoung JEONG, Suwon-si (KR); Jinwoo HAN, Suwon-si (KR)

(73) Assignee: Samsung Electronics Co., Ltd., Suwon-si (KR)

(21) Appl. No.: 18/640,513

(22) Filed: Apr. 19, 2024

(30) Foreign Application Priority Data
Jun. 15, 2023 (KR) 10-2023-0077010

(51) Int. Cl. H10B 12/00

(52) U.S. Cl. CPC H10B 12/315; H10B 12/05; H10B 12/482; H10B 12/50

(57) ABSTRACT

A semiconductor memory device includes a plurality of word lines extending in a first horizontal direction, a plurality of back gate lines extending in the first horizontal direction and alternately arranged with the plurality of word lines in a second horizontal direction different from the first horizontal direction, a plurality of channel layers extending in a vertical direction between a word line and a back gate line adjacent to each other among the plurality of word lines and the plurality of back gate lines, to correspond to columns in the first horizontal direction, a plurality of bit lines extending in the second horizontal direction on the plurality of word lines, the plurality of back gate lines, and the plurality of channel layers and electrically connected to the plurality of channel layers, and a plurality of memory structures electrically connected to the plurality of channel layers.

### CROSS-REFERENCE TO RELATED APPLICATION

This application is based on and claims priority under 35 U.S.C. § 119 to Korean Patent Application No. 10-2023-0077010, filed on Jun. 15, 2023, in the Korean Intellectual Property Office, the disclosure of which is incorporated by reference herein in its entirety.

### BACKGROUND

Various example embodiments relate to a semiconductor memory device, and more particularly, to a semiconductor memory device including a vertical channel transistor.

As the degree of integration of semiconductor memory devices increases, the degree of integration of semiconductor devices including semiconductor memory devices is also increasing. Accordingly, to increase the degree of integration of semiconductor devices, a vertical channel transistor formed vertically on a semiconductor substrate has been introduced instead of a planar channel transistor formed flat on a semiconductor substrate.

### SUMMARY

Various example embodiments provide a semiconductor memory device including vertical channel transistors having high degree of integration.

According to some example embodiments, there is provided a semiconductor memory device including a plurality of word lines extending in a first horizontal direction, a plurality of back gate lines extending in the first horizontal direction and alternately arranged with the plurality of word lines in a second horizontal direction different from the first horizontal direction, a plurality of channel layers extending in a vertical direction between a word line and a back gate line adjacent to each other among the plurality of word lines and the plurality of back gate lines, to correspond to columns in the first horizontal direction, a plurality of bit lines extending in the second horizontal direction on the plurality of word lines, the plurality of back gate lines, and the plurality of channel layers and electrically connected to the plurality of channel layers, and a plurality of memory structures including a plurality of lower electrodes, an upper electrode on the plurality of lower electrodes, and a dielectric layer between the plurality of lower electrodes and the upper electrode, the plurality of lower electrodes being electrically connected to the plurality of channel layers,.

Alternatively or additionally according to various example embodiments, there is provided a semiconductor memory device including a plurality of word line structures including a plurality of word lines and a plurality of gate insulating layers covering the plurality of word lines, the plurality of word lines extending in a first horizontal direction and having a constant width in a second horizontal direction orthogonal to the first horizontal direction, a plurality of back gate structures including a plurality of back gate lines extending in the first horizontal direction and a plurality of back gate insulating layers covering the plurality of back gate lines and arranged between the plurality of word line structures, a plurality of channel layers extending in a vertical direction between a word line structure and a back gate line structure adjacent to each other in the second horizontal direction among the plurality of word line structures and the plurality of back gate structures, to correspond to a column in the first horizontal direction, a device isolation film between a word line and a back gate line adjacent to each other among the plurality of word lines and the plurality of back gate insulating layers, a plurality of bit lines electrically connected to the plurality of channel layers and extending in the second horizontal direction on a transistor structure including the plurality of word line structures, the plurality of back gate structures, and the plurality of channel layers, and a plurality of memory structures including a plurality of lower electrodes, an upper electrode on the plurality of lower electrodes, and a dielectric layer between the plurality of lower electrodes and the upper electrode, the plurality of lower electrodes being electrically connected to the plurality of channel layers.

Alternatively or additionally according to some example embodiments, there is provided a semiconductor memory device including a peripheral circuit structure including a plurality of peripheral circuits, a plurality of word line structures on the peripheral circuit structure and including a plurality of word lines and a plurality of gate insulating layers covering the plurality of word lines, the plurality of word lines extending in a first horizontal direction and having a constant width in a second horizontal direction orthogonal to the first horizontal direction, a plurality of back gate structures arranged on the peripheral circuit structure and including a plurality of back gate lines and a plurality of back gate insulating layers covering the plurality of back gate lines, the plurality of back gate lines being alternately arranged with the plurality of word lines in the second horizontal direction and extending in the first horizontal direction, a plurality of channel layers extending in a vertical direction between a word line structure and a back gate line structure adjacent to each other in the second horizontal direction among the plurality of word line structures and the plurality of back gate structures, to correspond to a column in the first horizontal direction, a device isolation film located between a word line and a back gate insulating layer adjacent to each other among the plurality of word lines and the plurality of back gate insulating layers, a plurality of bit lines extending in the second horizontal direction on the plurality of word line structures, the plurality of back gate structures, and the plurality of channel layers and electrically connected to one end of the plurality of channel layers in a vertical direction, and a plurality of memory structures including a plurality of lower electrodes, an upper electrode on the plurality of lower electrodes, and a dielectric layer located between the plurality of lower electrodes and the upper electrode, the plurality of lower electrodes being electrically connected to another end of the plurality of channel layers in the vertical direction, wherein the plurality of word lines, the plurality of bit lines, and the plurality of channel layers correspond to a plurality of vertical channel transistors.

### BRIEF DESCRIPTION OF THE DRAWINGS

Embodiments of the inventive concept will be more clearly understood from the following detailed description taken in conjunction with the accompanying drawings in which:

FIG. 1 is a plan layout illustrating a semiconductor memory device according to various example embodiments; FIG. 2 is a perspective view of a semiconductor memory device according to various example embodiments;

FIGS. 3 to 18D are diagrams for explaining a method of manufacturing a semiconductor memory device according to various example embodiments; FIGS. 19A to 19D are cross-sectional views each illustrating a semiconductor memory device according to various example embodiments;

FIGS. 20A to 20C, 21A to 21C, 22A to 22C, 23A to 23C, and 24A to 24C are plan views each illustrating main components of a semiconductor memory device according to various example embodiments;

FIGS. 25A to 25D are diagrams for explaining a method of manufacturing a semiconductor memory device according to various example embodiments; FIGS. 26A to 26D are cross-sectional views each illustrating a semiconductor memory device according to various example embodiments;

FIGS. 27A to 27D are diagrams for explaining a method of manufacturing a semiconductor memory device according to various example embodiments; FIGS. 28A to 28D are cross-sectional views each illustrating a semiconductor memory device according to various example embodiments;

FIGS. 29A to 33D are diagrams for explaining a method of manufacturing a semiconductor memory device according to various example embodiments; FIGS. 34A to 34D are cross-sectional views each illustrating a semiconductor memory device according to various example embodiments; and

FIGS. 35A to 35D and 36A to 36D are cross-sectional views each illustrating a semiconductor memory device according to various example embodiments.

### DETAILED DESCRIPTION OF VARIOUS EXAMPLE EMBODIMENTS

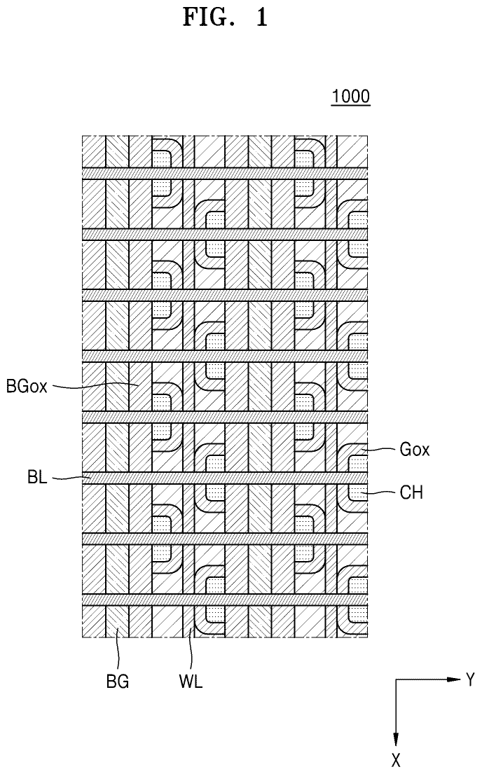

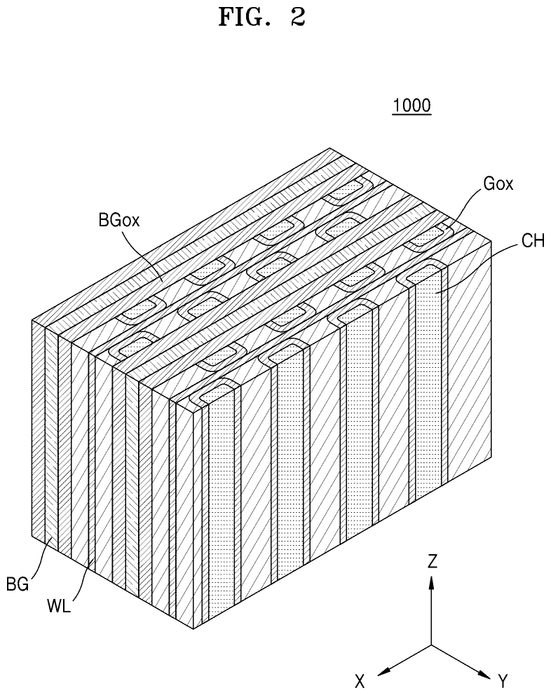

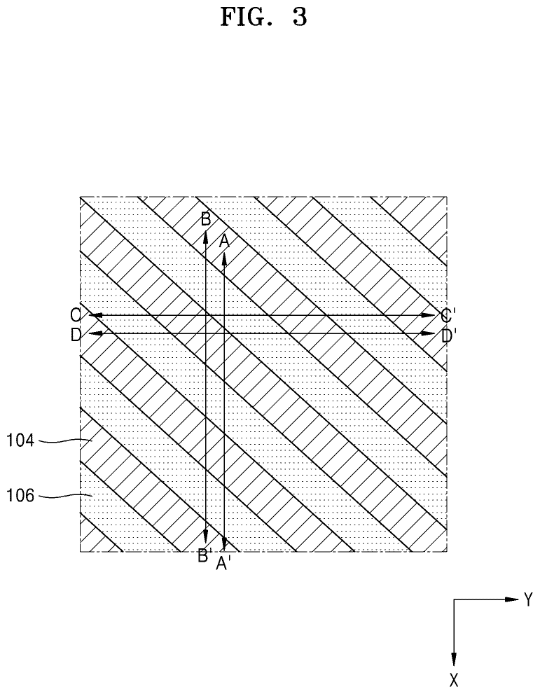

FIG. 1 is a plan layout illustrating a semiconductor memory device according to various example embodiments, and FIG. 2 is a perspective view of a semiconductor memory device according to various example embodiments.

Referring to FIGS. 1 and 2, a semiconductor memory device 1000 include a plurality of word lines WL extending in a first horizontal direction (e.g., an X direction), a plurality of bit lines BL extending in a second horizontal direction (e.g., a Y direction) different from the first horizontal direction (X direction), a plurality of back gate lines BG extending in the first horizontal direction (X direction), and a plurality of channel layers CH extending in a vertical direction (e.g., a Z direction). The first horizontal direction (X direction) and the second horizontal direction (Y direction) may be orthogonal to each other; example embodiments are not limited thereto.

In some example embodiments the plurality of word lines WL and the plurality of bit lines BL may correspond to a plurality of rows and a plurality of columns, respectively; example embodiments are not limited thereto. Alternatively or additionally, a number of the plurality of word lines WL may be the same as, greater than, or less than a number of the plurality of bit lines BL; example embodiments are not limited thereto. A number of back gate lines BG may be the same as or approximately the same as the number of word lines WL; example embodiments are not limited thereto.

The plurality of word lines WL and the plurality of back gate lines BG may be spaced apart from each other in the second horizontal direction (Y direction), and may extend in parallel to each other in the first horizontal direction (X direction). For example, the plurality of word lines WL and the plurality of back gate lines BG may be alternately arranged in the second horizontal direction (Y direction).

The plurality of channel layers CH may be arranged in a column (a horizontal column) in the first horizontal direction (X direction) between one word line WL and one back gate line BG, which are adjacent to each other among the plurality of word lines WL and the plurality of back gate lines BG. Channel layers CH arranged between a pair of back gate lines BG adjacent to each other among the plurality of back gate lines BG may be arranged in a zigzag manner in the first horizontal direction (X direction). For example, channel layers CH between a pair of back gate lines BG among the plurality of back gate lines BG may be arranged in a pair of columns extending in the first horizontal direction (X direction), and the channel layers CH arranged to form a pair of columns between the pair of back gate lines BG may be alternately arranged in a pair of columns to form a zigzag manner in the first horizontal direction (X direction).

A gate insulating layer Gox may be between a channel layer CH and a word line WL, and a back gate insulating layer BGox may be between a channel layer CH and a back gate line BG. In some example embodiments, the gate insulating layer Gox may be formed to surround at least a portion of the channel layer CH in a plan view. In some example embodiments, the back gate insulating layer BGox may extend in the first horizontal direction (X direction) along each of both sides of the back gate line BG in the second horizontal direction (Y direction). One side surface of the channel layer CH may be covered by the back gate insulating layer BGox, and other side surfaces may be covered by the gate insulating layer Gox. For example, when the channel layer CH has a rectangular shape or a shape similar to a rectangular shape, for example, a rectangular shape with rounded corners or a square shape with rounded or chamfered corners in a plan view, among four sides of edges of the channel layer CH, one side may be in contact with the back gate insulating layer BGox, and other three sides may be in contact with the gate insulating layer Gox. FIGS. 1 and 2 show that, in a plan view, the gate insulating layer Gox surrounds a portion of the channel layer CH, and the back gate insulating layer BGox surrounds the remaining portion of the channel layer CH, but this is for convenience of illustration, and the inventive concept is not limited thereto. In some example embodiments, the gate insulating layer Gox may completely surround the channel layer CH in a plan view. For example, the gate insulating layer Gox may be between the channel layer CH and the back gate insulating layer BGox.

The plurality of bit lines BL may be spaced apart from each other in the first horizontal direction (X direction), and may extend in parallel to each other in the second horizontal direction (Y direction). The plurality of bit lines BL may extend in the second horizontal direction (Y direction) and may be electrically connected to the plurality of channel layers CH. For example, the plurality of bit lines BL may be electrically connected to one end among first and second (or both) ends of the plurality of channel layers CH in the vertical direction (Z direction). One bit line BL may be electrically connected only to one of the channel layers CH arranged between a pair of back gate lines BG adjacent to each other among the plurality of back gate lines BG. Each of the pair of bit lines BL adjacent to each other in the first horizontal direction (X direction) may be electrically connected to channel layers CH arranged in different columns among the channel layers CH arranged to form a pair of columns between the pair of back gate lines BG.

The bit line BL or at least portions of the bit line BL, the word line WL or at least portions of the word line, the channel layer CH adjacent to a portion of the word line WL crossing the bit line BL in a plain view, and the gate insulating layer Gox between the word line WL and the channel layer CH may configure a transistor.

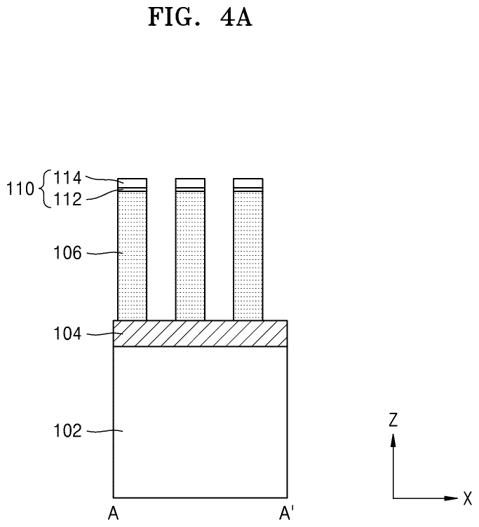

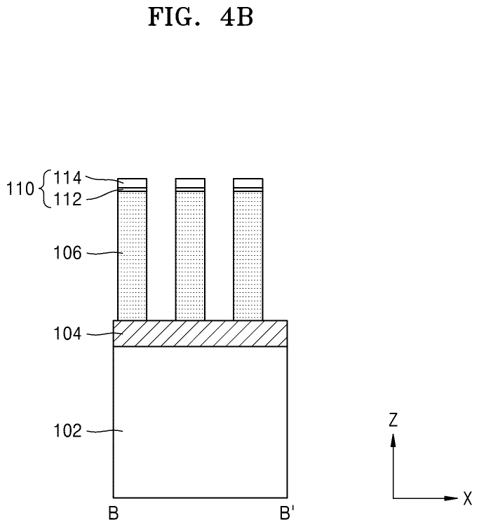

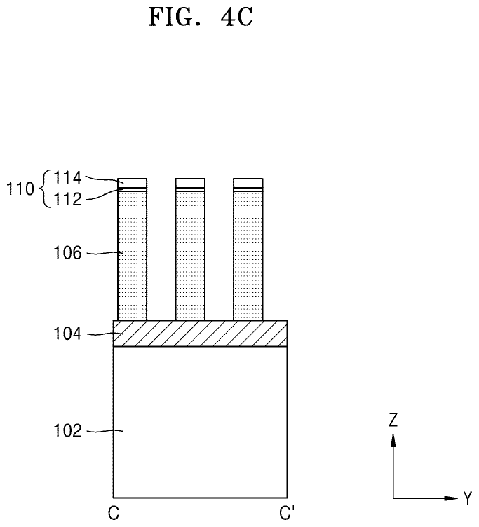

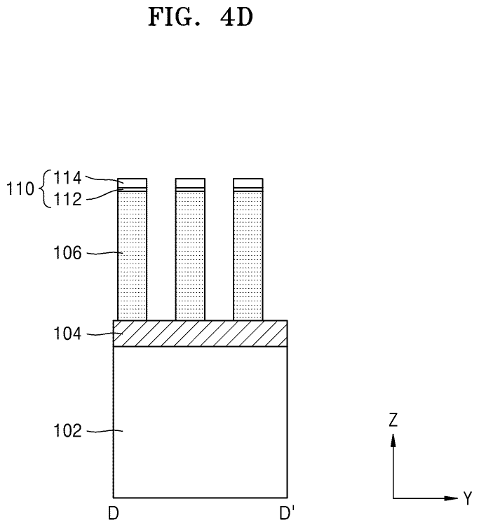

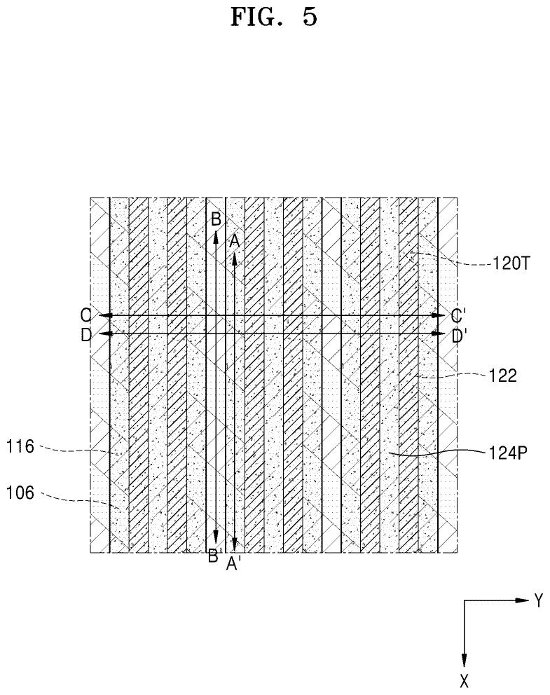

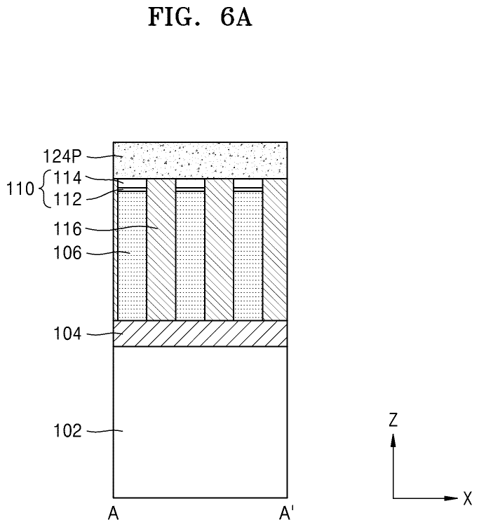

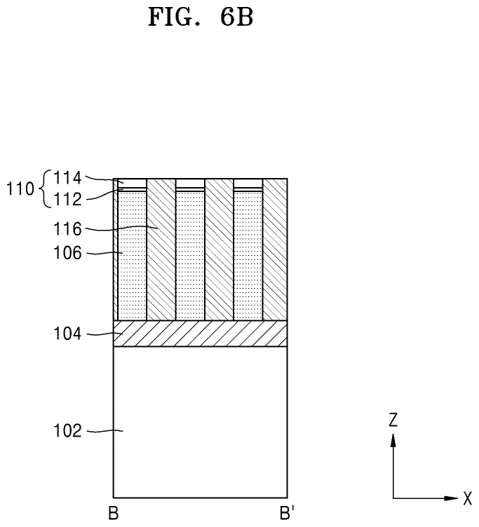

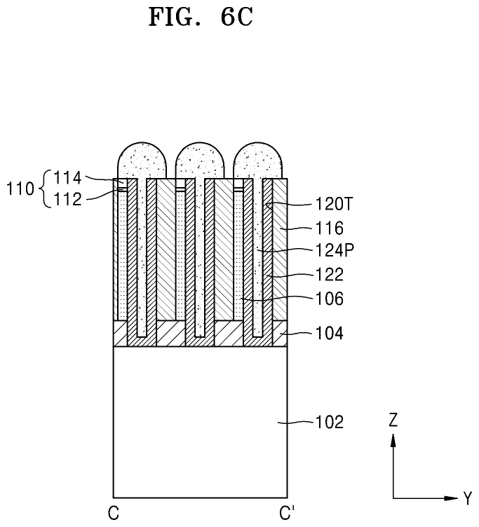

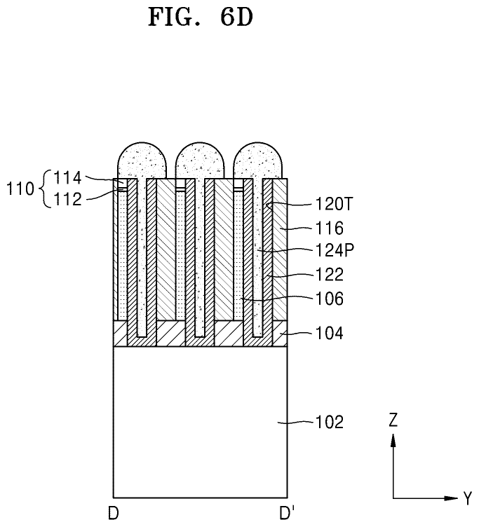

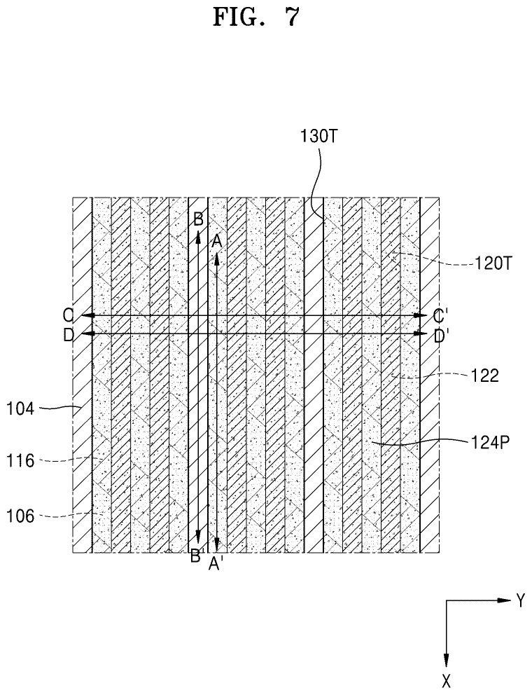

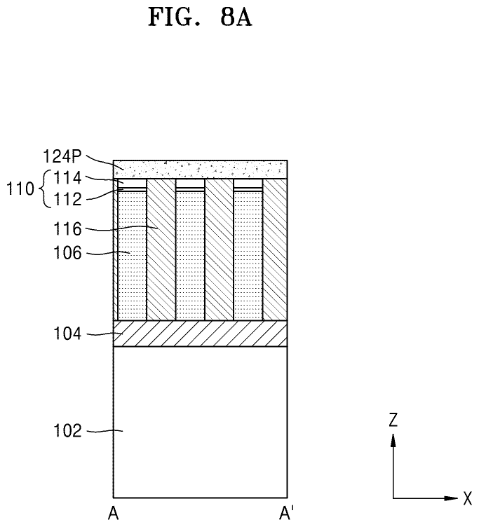

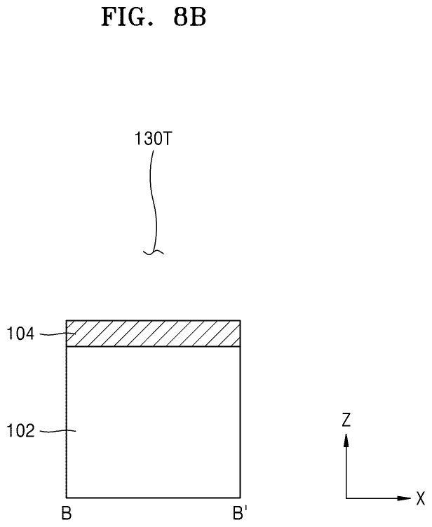

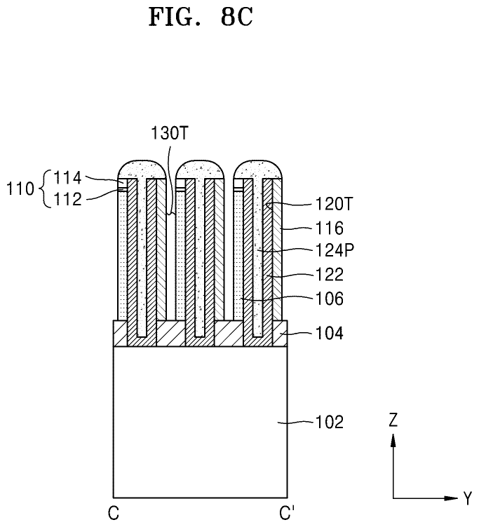

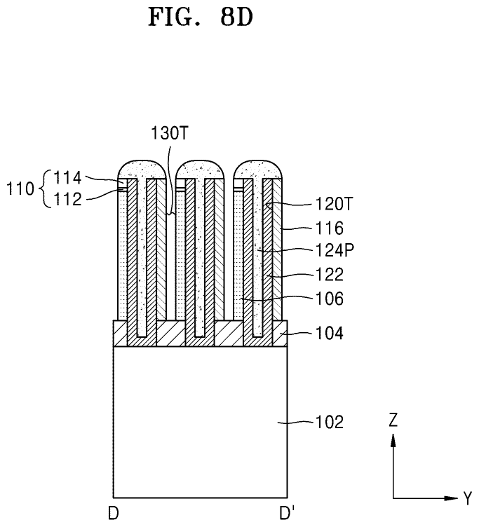

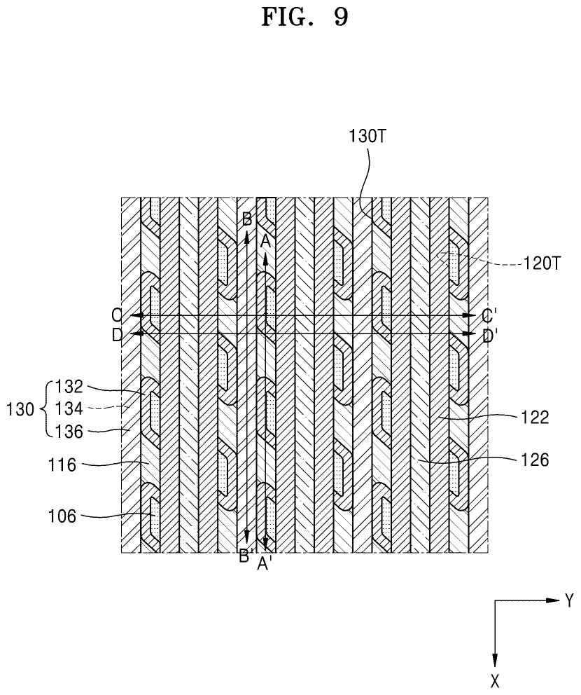

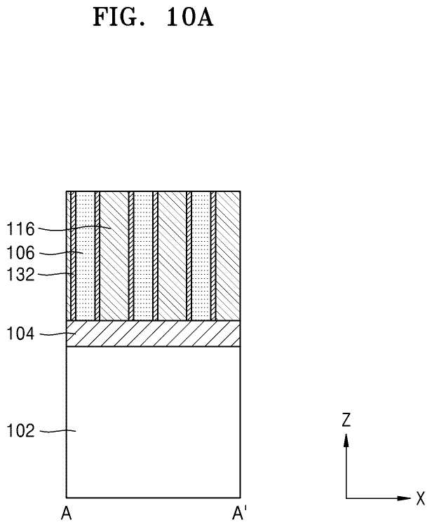

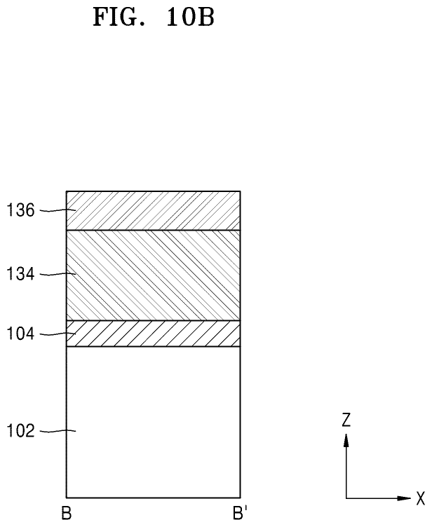

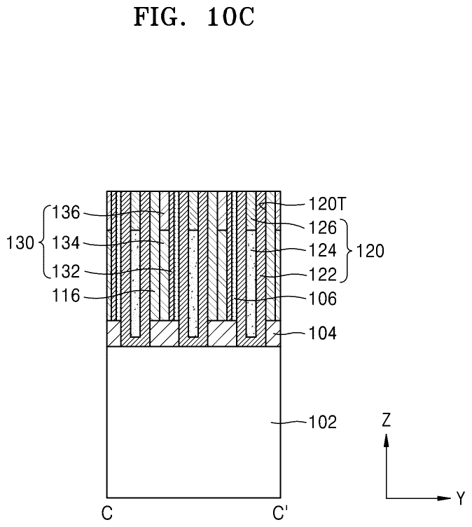

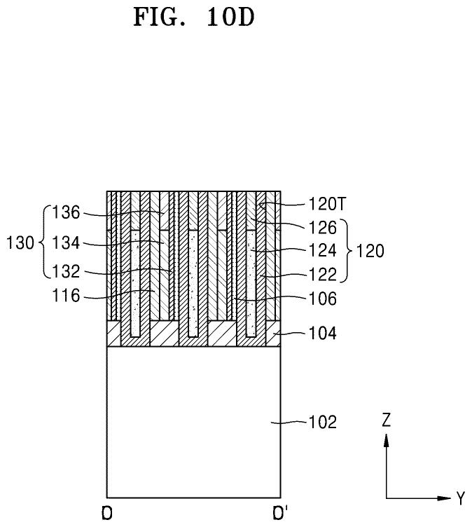

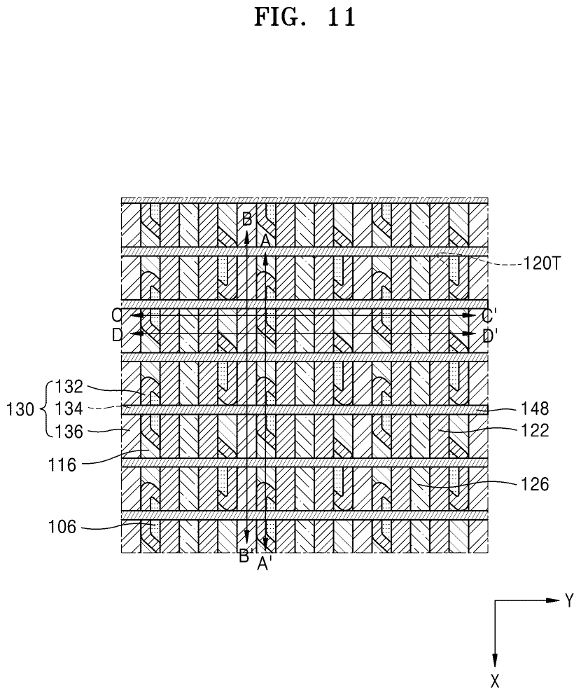

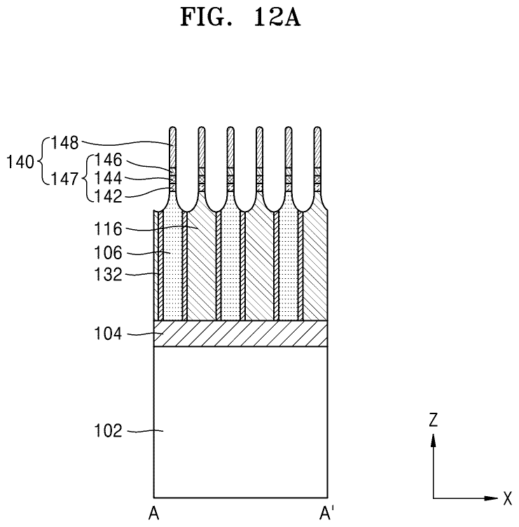

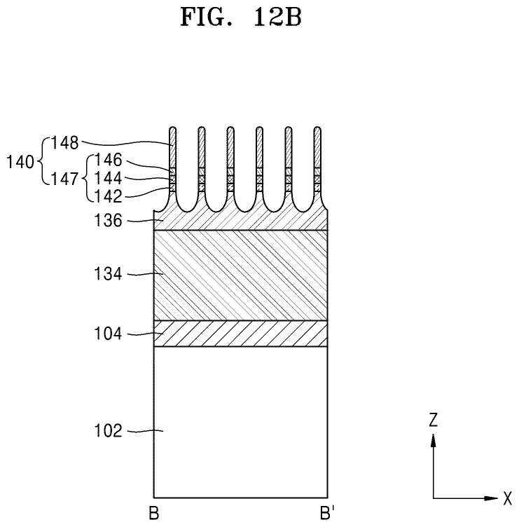

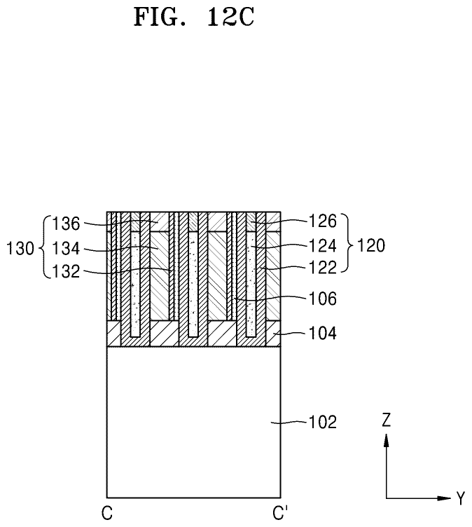

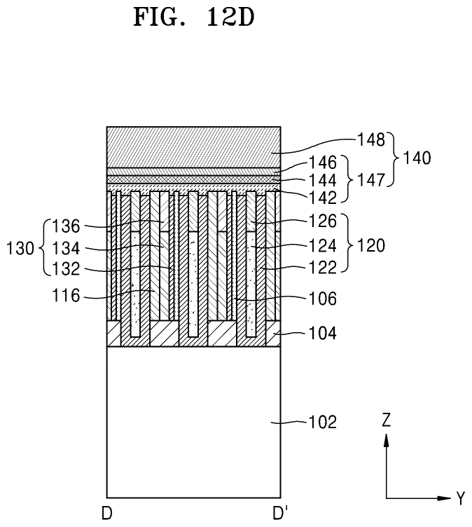

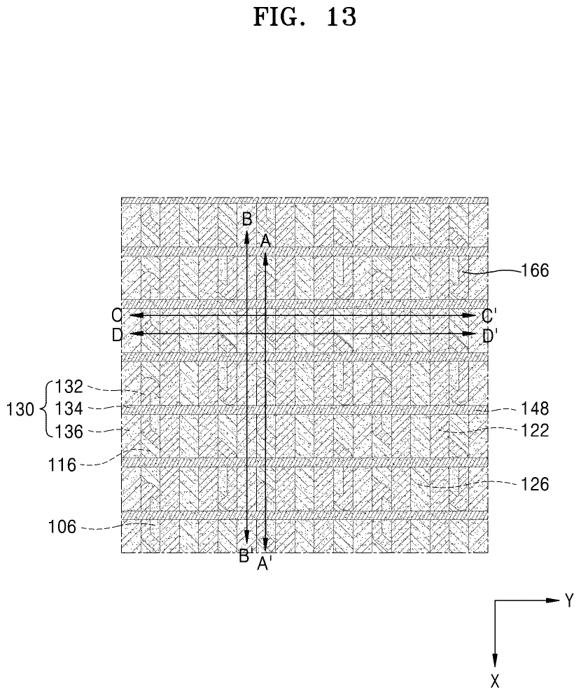

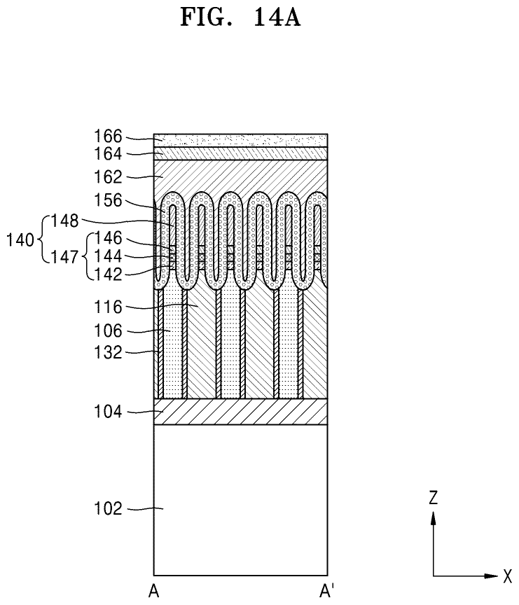

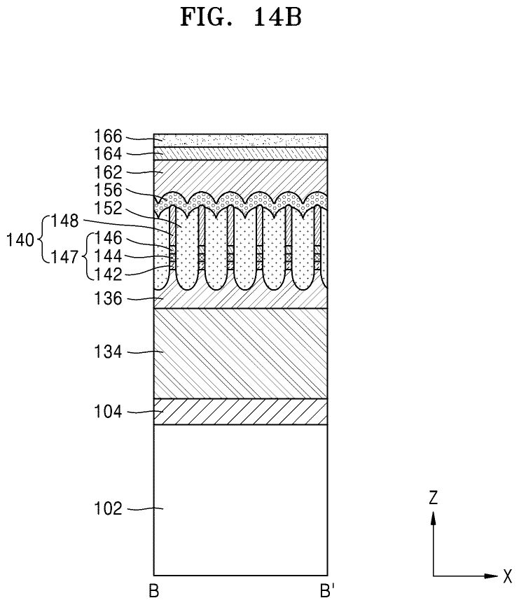

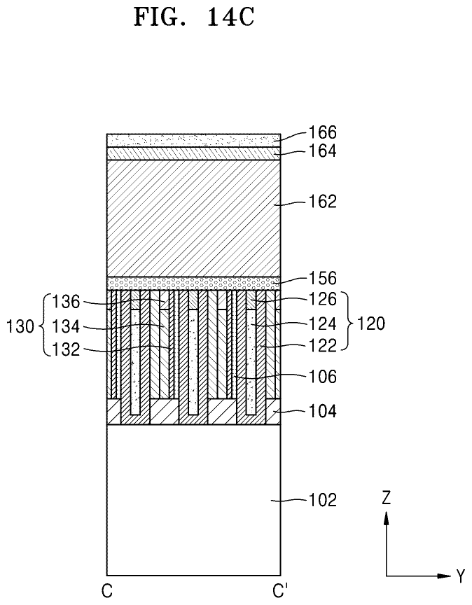

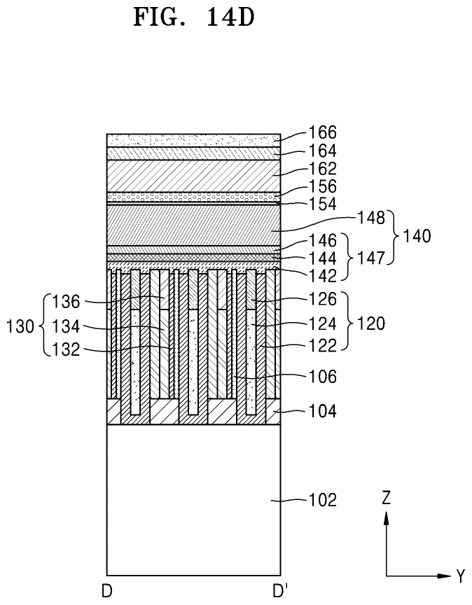

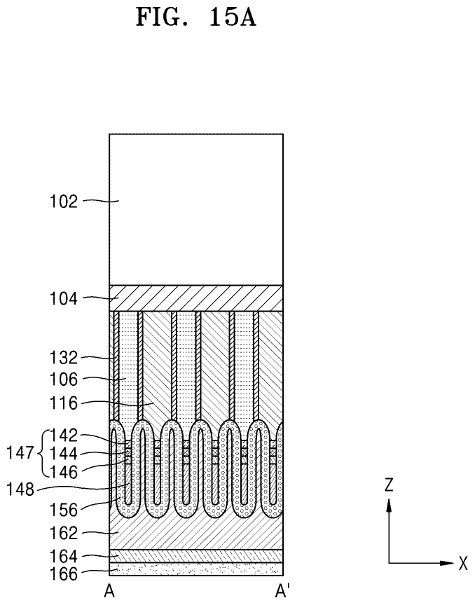

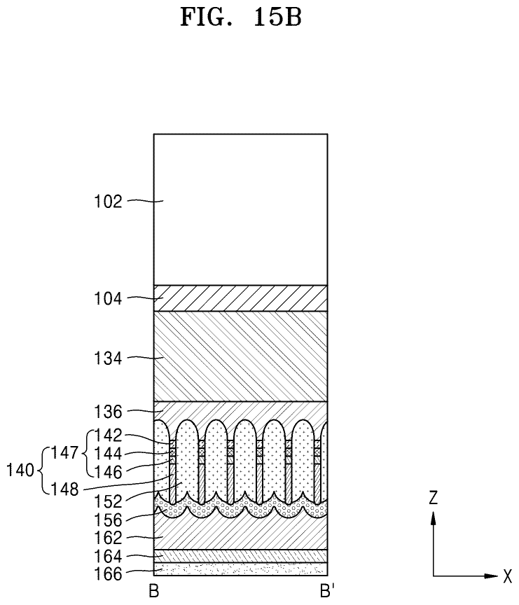

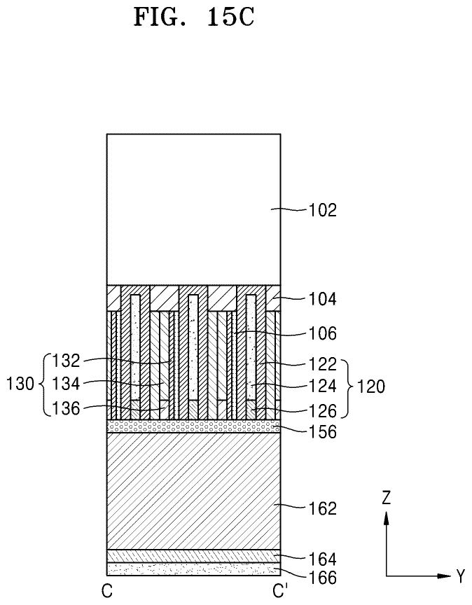

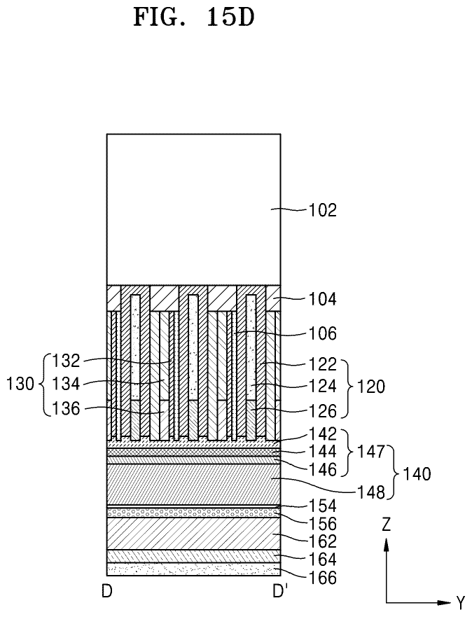

FIGS. 3 to 18D are diagrams for explaining a method of manufacturing a semiconductor memory device according to various example embodiments, and FIGS. 19A to 19D are cross-sectional views each illustrating a semiconductor memory device according to various example embodiments. In particular, FIGS. 3, 5, 7, 9, 11, and 13 are plain views for explaining a method of manufacturing a semiconductor memory device according to various example embodiments, FIGS. 4A, 4B, 4C, and 4D are cross-sectional views respectively taken along lines A-A′, B-B′, C-C′, and D-D′ of FIG. 3, FIGS. 6A, 6B, 6C, and 6D are cross-sectional views respectively taken along lines A-A′, B-B′, C-C′, and D-D′ of FIG. 5, FIGS. 8A, 8B, 8C, and 8D are cross-sectional views respectively taken along lines A-A′, B-B′, C-C′, and D-D′ of FIG. 7, FIGS. 10A, 10B, 10C, and 10D are cross-sectional views respectively taken along lines A-A′, B-B′, C-C′, and D-D′ of FIG. 9, FIGS. 12A, 12B, 12C, and 12D are cross-sectional views respectively taken along lines A-A′, B-B′, C-C′, and D-D′ of FIG. 11, FIGS. 14A, 14B, 14C, and 14D are cross-sectional views respectively taken along lines A-A′, B-B′, C-C′, and D-D′ of FIG. 13, FIGS. 15A, 16A, 17A, 18A, and 19A are cross-sectional views are cross-sectional views taken along the line A-A′ of FIG. 13, FIGS, 15B, 16B, 17B, 18B, and 19B are cross-sectional views taken along the line B-B′ of FIG. 13, FIGS. 15C, 16C, 17C, 18C, and 19C are cross-sectional views taken along the line C-C′ of FIG. 13, and FIGS. 15D, 16D, 17D, 18D, and 19D are cross-sectional views taken along the line D-D′ of FIG. 13.

In FIGS. 3, 5, 7, 9, 11, and 13, the lines (the cut line) A-A′ and B-B′ are for indicating different positions with respect to the second horizontal direction (Y direction), and the lines (the cut lines) C-C′ and D-D′ are for indicating different positions with respect to the first horizontal direction (X direction). Accordingly, in the cross-sectional views taken along the lines A-A′ and B-B′ of FIGS. 3, 5, 7, 9, 11, and 13, both ends in the first horizontal direction (X direction) may not coincide with both ends of the lines A-A′ and B-B′ of FIGS. 3, 5, 7, 9, 11, and 13, and in the cross-sectional views taken along the lines C-C′ and D-D′ of FIGS. 3, 5, 7, 9, 11, and 13, both ends in the second horizontal direction (Y direction) may not coincide with both ends of the lines C-C′ and D-D′ of FIGS. 3, 5, 7, 9, 11, and 13.

Referring to FIGS. 3 and 4A to 4D, after preparing a structure in which a base substrate 102, a base insulating layer 104, and a channel layer 106 are sequentially stacked, a plurality of mask patterns 110 are formed on the channel layer 106. In some example embodiments, the plurality of mask patterns 110 may be formed to extend in parallel to each other in a diagonal direction with respect to the first horizontal direction (X direction) and the second horizontal direction (Y direction). An angle of the diagonal direction with respect to the X direction may be 45 degrees; however, example embodiments are not limited thereto and the angle may be greater than 45 degrees or less than 45 degrees. Portions of the channel layer 106 are etched by using the plurality of mask patterns 110 as etch masks to separate the channel layer 106 into a plurality of channel layers 106. The base insulating layer 104 may be exposed on bottom surfaces of spaces from which the portions of the channel layer 106 are removed. In some example embodiments, the plurality of channel layers 106 separated as above may be formed to extend in parallel to each other in the diagonal direction with respect to the first horizontal direction (X direction) and the second horizontal direction (Y direction).

In some example embodiments, the structure in which the base substrate 102, the base insulating layer 104, and the channel layer 106 are sequentially stacked may be or may include or be included in a silicon-on-insulator (SOI) substrate or a germanium-on-insulator (GeOI) substrate. The base substrate 102 may include a semiconductor material. For example, the base substrate 102 may include a semiconductor element such as silicon (Si) and/or germanium (Ge), or may include at least one compound semiconductor selected from among silicon germanium (SiGc), silicon carbide (SiC), gallium arsenide (GaAs), indium arsenide (InAs), and indium phosphide (InP). The base insulating layer 104 may or may not include silicon oxide. In some example embodiments, the channel layer 106 may include a semiconductor material. For example, the channel layer 106 may include monocrystalline silicon and/or polysilicon. Alternatively or additionally, the channel layer 106 may include an oxide semiconductor material. The channel layer 106 may include at least one of a binary and/or ternary oxide semiconductor material including a first metal element, a ternary oxide semiconductor material including a first metal element and a second metal element that are different from each other, and a quaternary oxide semiconductor material including a first metal clement, a second metal element, and a third metal element that are different from each other.

The binary or ternary oxide semiconductor material may be, for example, one or more of zinc oxide (ZnₓO), gallium oxide (GaₓO), tin oxide (TiₓO), zinc oxynitride (ZnₓO_{y}N), indium zinc oxide (InₓZn_{y}O), gallium zinc oxide (GaₓZn_{y}O), tin zinc oxide (SnₓZn_{y}O), and tin gallium oxide (SnₓGa_{y}O), but inventive concepts are not limited thereto. The quaternary oxide semiconductor material may include, for example, any one or more of indium gallium zinc oxide (InₓGa_{y}Zn,O), indium gallium silicon oxide (InₓGa_{y}Si,O), indium tin zinc oxide (InₓSn_{y}ZnzO), indium gallium tin oxide (InₓGa_{y}Sn_{z}O), zirconium zinc tin oxide (ZrₓZn_{y}Sn_{z}O), hafnium indium zinc oxide (HfₓIn_{Y}Zn_{z}O), gallium zinc tin oxide (GaₓZn_{Y}Sn_{z}O), aluminum zinc tin oxide (AlₓZn_{y}Sn_{z}O), ytterbium gallium zinc oxide (YbₓGa_{Y}Zn_{z}O), and indium aluminum zinc oxide (InₓAl_{y}Zn_{z}O), but inventive concepts are not limited thereto.

In some example embodiments, the channel layer 106 may include a crystalline oxide semiconductor material and/or an amorphous oxide semiconductor material. When the channel layer 106 includes a crystalline oxide semiconductor material, the channel layer 106 may have at least one crystallinity of single crystalline, polycrystalline, spinel, and c-axis aligned crystalline (CAAC). In some example embodiments, the channel layer 106 may be formed by stacking at least two layers including a first layer including a crystalline oxide semiconductor material and a second layer including an amorphous oxide semiconductor material. For example, the channel layer 106 may be formed by sequentially stacking a first layer including a crystalline oxide semiconductor material, a second layer including an amorphous oxide semiconductor material, and a third layer including a crystalline oxide semiconductor material.

In some example embodiments, the plurality of mask patterns 110 may each have a stacked structure of a lower mask pattern 112 and an upper mask pattern 114. For example, the lower mask pattern 112 may include an oxide, and the upper mask pattern 114 may include a nitride.

Referring to FIGS. 5 and 6A to 6D, after forming a plurality of device isolation films 116 filling spaces between the plurality of channel layers 106 (e.g., with a chemical vapor deposition (CVD) process and/or an atomic layer deposition (ALD) process and/or a spin-on glass (SOG) process), a plurality of back gate line trenches 120T are formed by performing a patterning process of removing a portion of each of the plurality of channel layers 106 and the plurality of device isolation films 116. The plurality of back gate line trenches 120T may be spaced apart from each other in the second horizontal direction (Y direction), and may extend in parallel to each other in the first horizontal direction (X direction). In some example embodiments, in a process of forming the plurality of back gate line trenches 120T, a portion of the base insulating layer 104, which is below a portion of each of the plurality of channel layers 106 and the plurality of device isolation films 116, may be further removed. In some example embodiments, the plurality of back gate line trenches 120T may penetrate the plurality of channel layers 106, the plurality of device isolation films 116, and the base insulating layer 104, so that the base substrate 102 may be exposed on bottom surfaces of the plurality of back gate line trenches 120T, but inventive concepts are not limited thereto. Alternatively or additionally, the plurality of back gate line trenches 120T may penetrate the plurality of channel layers 106 and the plurality of device isolation films 116 but may not penetrate the base insulating layer 104, so that the base insulating layer 104 may not be exposed on the bottom surfaces of the plurality of back gate line trenches 120T.

Hereinafter, a back gate insulating layer 122 covering a bottom surface and an inner wall of each of the plurality of back gate line trenches 120T and a back gate line material layer 124P on the back gate insulating layer 122 are formed. A plurality of back gate insulating layers 122 may be formed to conformally cover the bottom surfaces and inner walls of the plurality of back gate line trenches 120T without filling all of the plurality of back gate line trenches 120T, and a plurality of back gate line material layers 124P may be formed to cover the plurality of back gate insulating layers 122 and fill all of the plurality of back gate line trenches 120T. The plurality of back gate line material layers 124P may be formed to fill all of the plurality of back gate line trenches 120T and protrude to the outside of the plurality of back gate line trenches 120T. For example, a vertical level of the uppermost end of the back gate line material layer 124P may be higher than (or above) a vertical level of upper surfaces of the plurality of mask patterns 110.

The back gate insulating layer 122 may include at least one selected from silicon oxide, silicon nitride, oxide/nitride/oxide (ONO), and high-k dielectrics having a dielectric constant higher than that of silicon oxide. For example, the back gate insulating layer 122 may have a dielectric constant from about 10 to about 25. The back gate line material layer 124P may include a semiconductor material, a metal material, a conductive metal nitride, or a combination thereof. In some example embodiments, the back gate line material layer 124P may include doped silicon, Al, Cu, Ti, Ta, Ru, W, Mo, Pt, Ni, Co, TIN, TaN, WN, NbN, TiAl, TiAlN, TiSi, TiSiN, TaSi, TaSiN, RuTiN, NiSi, CoSi, IrOₓ, RuOₓ, or a combination thereof.

Referring to FIGS. 7 and 8A to 8D, a plurality of word line recesses 130T are formed by performing a patterning process of removing a portion of each of the plurality of channel layers 106 and the plurality of device isolation films 116. The plurality of word line recesses 130T may be spaced apart from each other in the second horizontal direction (Y direction), and may extend in parallel to each other in the first horizontal direction (X direction). One word line recess 130T may extend between a pair of back gate line trenches 120T, which are adjacent to each other in the second horizontal direction (Y direction), in the first horizontal direction (X direction). The plurality of back gate line trenches 120T and the plurality of word line recesses 130T may be spaced apart from each other in the second horizontal direction (Y direction), and may extend in parallel each other in the first horizontal direction (X direction). For example, the plurality of back gate line trenches 120T and the plurality of word line recesses 130T may be alternately arranged in the second horizontal direction (Y direction). In some example embodiments, one word line recess 130T may extend between a pair of back gate line trenches 120T, which are adjacent to each other in the second horizontal direction (Y direction), in the first horizontal direction (X direction), and one back gate line trench 120T may extend between a pair of word line recesses 130T, which are adjacent to each other in the second horizontal direction (Y direction), in the first horizontal direction (X direction).

The plurality of word line recesses 130T may be formed by performing an etching process of removing a portion of each of the plurality of channel layers 106 and the plurality of device isolation films 116 by using the plurality of back gate line material layers 124P as etch masks. For example, the plurality of back gate line material layers 124P may perform a function of self-aligned masks. The plurality of word line recesses 130T may penetrate the plurality of channel layers 106 and the plurality of device isolation films 116, so that the base insulating layer 104 may be exposed on bottom surfaces of the plurality of word line recesses 130T.

Referring to FIGS. 9 and 10A to 10D, a plurality of back gate structures 120 each including the back gate insulating layer 122, a back gate line 124, and a back gate capping layer 126 and a plurality of word line structures 130 each including a gate insulating layer 132, a word line 134, and a word line capping layer 136 are formed. The plurality of back gate structures 120, the plurality of word line structures 130, and the plurality of channel layers 106 may be referred to as a transistor structure. The plurality of word line structures 130 and the plurality of channel layers 106 of the transistor structure may or may respectively configure a plurality of transistors. The plurality of transistors may each be a vertical channel transistor (VCT).

The back gate line 124 may be formed by removing a portion of an upper side of the back gate line material layer 124P shown in FIGS. 7, 8A, 8C, and 8D. For example, the back gate line 124 may be formed by removing, among the back gate line material layer 124P, a portion protruding to the outside of the back gate line trench 120T and a portion filling an upper space of the back gate line trench 120T. Thereafter, the back gate capping layer 126 filling the upper space of the back gate line trench 120T may be formed to form a back gate structure 120 including the back gate insulating layer 122, the back gate line 124, and the back gate capping layer 126.

The back gate insulating layer 122 may be between the channel layer 106 and the back gate line 124, and the gate insulating layer 132 may be between the channel layer 106 and the word line 134. In some example embodiments, the back gate insulating layer 122 may extend in the first horizontal direction (X direction) along each of both sides of the back gate line 124 in the second horizontal direction (Y direction). In some example embodiments, the gate insulating layer 132 may be formed to surround at least a portion of the channel layer 106 in a plan view.

The word line 134 and the word line capping layer 136 may be formed to fill the word line recess 130T. For example, after the word line 134 filling a portion of a lower side of the word line recess 130T is formed, the word line capping layer 136 filing the word line recess 130T may be formed on the word line 134 to form a word line structure 130 including the gate insulating layer 132, the word line 134, and the word line capping layer 136. The word line 134 and the word line capping layer 136 may have a constant horizontal width in the second horizontal direction (Y direction) and extend in the first horizontal direction (X direction).

The channel layer 106, the gate insulating layer 132, and a device isolation film 116 may be between the back gate insulating layer 122 and the word line 134, which are adjacent to each other in the second horizontal direction (Y direction). In a plan view, the device isolation film 116 may fill a space between two gate insulating layers 132 surrounding two channel layers 106 adjacent to each other in the first horizontal direction (X direction).

The gate insulating layer 132 may include at least one selected from silicon oxide, silicon nitride, ONO, and high-k dielectrics having a dielectric constant higher than that of silicon oxide. For example, the gate insulating layer 132 may have a dielectric constant from about 10 to about 25. The word line 134 may include a semiconductor material, a metal material, a conductive metal nitride, or a combination thereof. In some example embodiments, the word line 134 may include doped silicon, Al, Cu, Ti, Ta, Ru, W, Mo, Pt, Ni, Co, TiN, TaN, WN, NbN, TiAl, TiAlN, TiSi, TiSiN, TaSi, TaSIN, RuTiN, NiSi, CoSi, IrOₓ, RuOₓ, or a combination thereof. The word line capping layer 136 may include silicon nitride.

Referring to FIGS. 11 and 12A to 12D, a plurality of bit line structures 140 are formed on the plurality of back gate structures 120, the plurality of word line structures 130, and the plurality of channel layers 106. The plurality of bit line structures 140 may be spaced apart from each other in the first horizontal direction (X direction), and may extend in parallel to each other in the second horizontal direction (Y direction). The plurality of bit line structures 140 may each include a bit line 147 and an insulating capping line 148 covering the bit line 147. A plurality of bit lines 147 and a plurality of insulating capping lines 148 may be spaced apart from each other in the first horizontal direction (X direction), and may extend in parallel to each other in the second horizontal direction (Y direction). For example, the plurality of insulating capping lines 148 may each include silicon nitride.

Each of the plurality of bit lines 147 may include doped polysilicon, metal, conductive metal nitride, conductive metal silicide, conductive metal oxide, or a combination thereof. For example, the bit line 147 may include polysilicon such as doped polysilicon, Al, Cu, Ti, Ta, Ru, W, Mo, Pt, Ni, Co, TIN, TaN, WN, NbN, TiAl, TiAlN, TiSi, TiSiN, TaSi, TaSiN, RuTiN, NiSi, CoSi, IrOₓ, RuOₓ, or a combination thereof, but inventive concepts are not limited thereto. Alternatively or additionally, the bit line 147 may include a two-dimensional semiconductor material. The two-dimensional semiconductor material may include, for example, graphene, carbon nanotube, or a combination of graphene and carbon nanotube. The bit line 147 may include a single layer or a multi-layer, each including the above conductive materials.

In some example embodiments, each of the plurality of bit lines 147 may have a stacked structure of a first line pattern 142, a second line pattern 144, and a third line pattern 146. For example, the first line pattern 142 may include a semiconductor material, and each of the second line pattern 144 and the third line pattern 146 may include a metal-based material. The second line pattern 144 and the third line pattern 146 may include metal-based materials of the same or of different types. For example, the first line pattern 142 may include doped polysilicon. For example, the second line pattern 144 may include titanium nitride (TiN) or Ti—Si—N (TSN), and the third line pattern 146 may include tungsten (W) or tungsten silicide (WSiₓ). In some example embodiments, the second line pattern 144 may function as a diffusion barrier.

Referring to FIGS. 13 and 14A to 14D, a plurality of filling insulating layers 152 filling a portion of each of spaces between the plurality of bit line structures 140 and a cover insulating layer 156 covering the plurality of bit line structures 140 and the plurality of filling insulating layers 152 are formed. In some example embodiments, a bit line cover insulating layer 154 may be formed on a portion of upper surfaces of the plurality of bit line structures 140. The cover insulating layer 156 may be formed to conformally cover the plurality of filling insulating layers 152 and the plurality of bit line structures 140, and may not completely fill spaces between the plurality of bit line structures 140. In some example embodiments, the plurality of filling insulating layers 152 may not be formed, and the cover insulating layer 156 may be formed to conformally cover the plurality of bit line structures 140, and may not completely fill spaces between the plurality of bit line structures 140. In some example embodiments, the plurality of filling insulating layers 152 and the bit line cover insulating layer 154 may be formed only on an edge portion of a memory cell array of a semiconductor memory device 1 shown in FIGS. 19A to 19D in a plan view. Each of a filling insulating layer 152 and the cover insulating layer 156 may include silicon oxide. The bit line cover insulating layer 154 may include silicon nitride.

Thereafter, a shield conductive layer 162 covering the cover insulating layer 156 and filling the spaces between the plurality of bit line structures 140, a protective insulating layer 164 covering the shield conductive layer 162, and a first bonding insulating layer 166 covering the protective insulating layer 164 may be sequentially formed. The shield conductive layer 162 may prevent or reduce the likelihood of and/or impact from interference between the plurality of bit lines 147. For example, the shield conductive layer 162 may include a metal material. For example, the protective insulating layer 164 may include silicon nitride. For example, the first bonding insulating layer 166 may include silicon oxide or silicon carbonitride (SiCN).Referring to FIGS. 15A to 15D, a resultant shown in FIGS. 13 to 14D is turned upside down so that the base substrate 102 is positioned at the upper side, and the first bonding insulating layer 166 is positioned at the lower side.

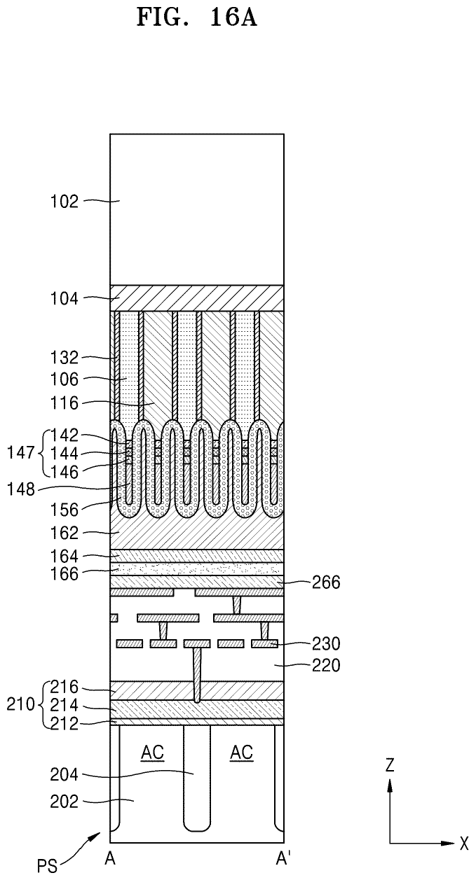

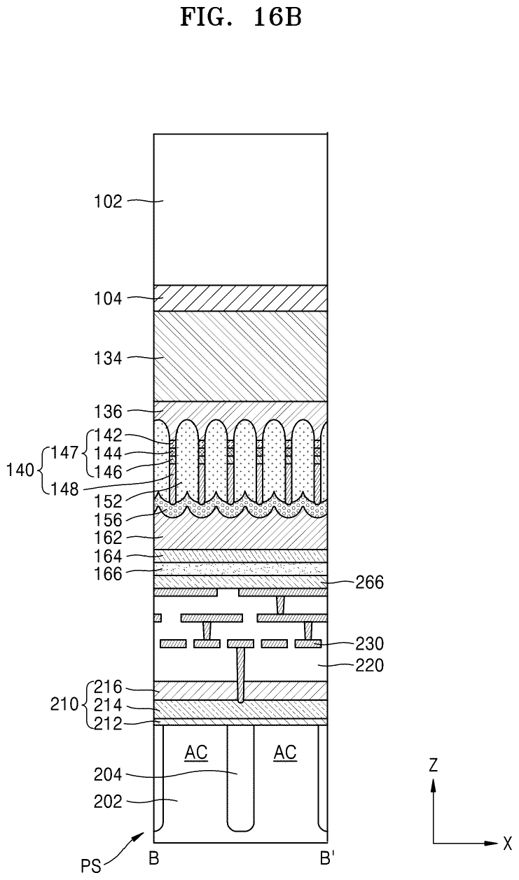

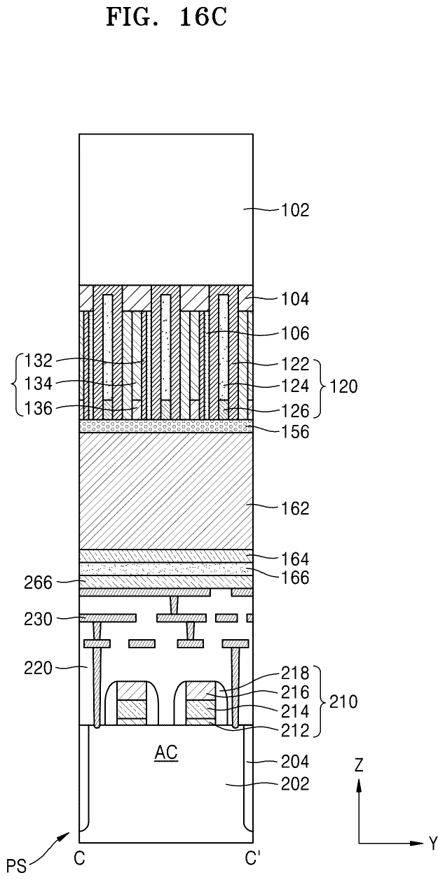

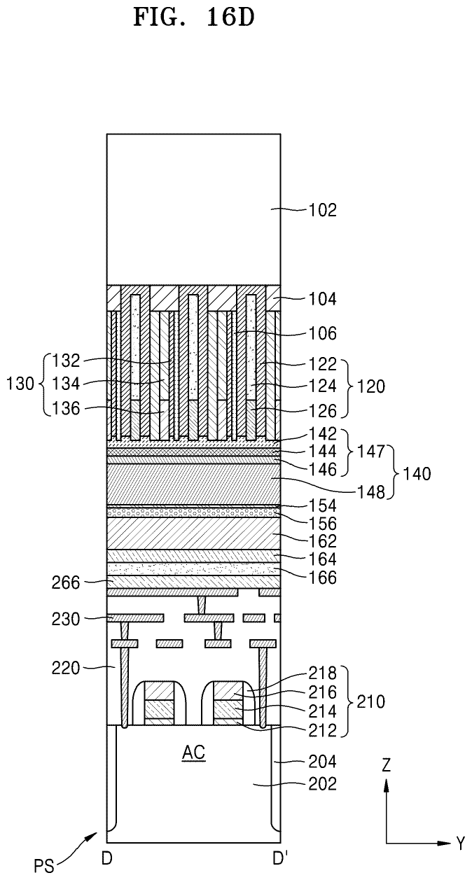

Referring to FIGS. 16A to 16D, a resultant shown in FIGS. 15A to 15D is bonded to a peripheral circuit structure PS. The peripheral circuit structure PS and the resultant shown in FIGS. 15A to 15D may be bonded to each other by a hybrid bonding method.

The peripheral circuit structure PS may include a circuit substrate 202 having an active area AC defined by a circuit element isolation film 204, a circuit gate structure 210 arranged on the active area AC of the circuit substrate 202, an inter wiring insulating layer 220 covering the circuit gate structure 210 on the circuit substrate 202, a wiring structure 230 surrounded by the inter wiring insulating layer 220 and electrically connected to the active area AC and/or the circuit gate structure 210, and a second bonding insulating layer 266 arranged on the inter wiring insulating layer 220 and the wiring structure 230.

The peripheral circuit structure PS may be fabricated separately from the resultant shown in FIGS. 15A to 15D. In some example embodiments, both the peripheral circuit structure PS and the resultant shown in FIGS. 15A to 15D may be wafers for wafer-to-wafer (W2W) bonding; alternatively in some example embodiments, both the peripheral circuit structure PS and the resultant shown in FIGS. 15A to 15D may be chips for chip-to-chip (C2C) bonding; example embodiments are not limited thereto.

The circuit substrate 202 may include the same, or different, material than that of base substrate 102. The circuit substrate 202 may include, for example, a semiconductor material, such as a Group IV semiconductor material, a Group III-V semiconductor material, a Group II-VI semiconductor material, and a Group II-VI oxide semiconductor material. The Group IV semiconductor material may include, for example, silicon (Si), germanium (Ge), or silicon-germanium (Si—Ge). The Group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The Group II-VI semiconductor material may include, for example, zinc telluride (ZnTe) or cadmium sulfide (CdS). The circuit substrate 202 may be a bulk wafer or an epitaxial layer. In some example embodiments, the circuit substrate 202 may be provided as a bulk wafer or an epitaxial layer. Alternatively or additionally, the circuit substrate 202 may include an SOI substrate or a GeOI substrate. The active area AC may be defined by the circuit element isolation film 204 in the circuit substrate 202, and the active area AC and the circuit gate structure 210 may configure a plurality of peripheral circuits.

The circuit gate structure 210 may include a circuit gate electrode 214 on the active arca AC, a circuit gate insulating layer 212 between the active area AC and the circuit gate electrode 214, a circuit gate capping layer 216 covering the circuit gate electrode 214, and a circuit gate spacer 218 covering side surfaces of the circuit gate insulating layer 212, the circuit gate electrode 214, and the circuit gate capping layer 216.

The wiring structure 230 may include a circuit wiring and a circuit wiring contact. The wiring structure 230 may include a conductive material, such as copper (Cu), aluminum (Al), tungsten (W), silver (Ag), gold (Au), or a combination thereof. The inter wiring insulating layer 220 may include an insulating material capable of including silicon oxide, silicon nitride, a low-k material, or a combination thereof. The low-k material may be a material having a lower dielectric constant than that of silicon oxide, and may include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. In some example embodiments, the inter wiring insulating layer 220 may include an ultra-low-k (ULK) film having an ultra-low dielectric constant K of about 2.2 to about 2.4. The ULK film may include SiOC or SiCOH.

Although FIG. 16D illustrates that the circuit gate structure 210 extends in the X direction, example embodiments are not limited thereto. Alternatively or additionally, although FIG. 16D illustrates that the circuit gate structure 210 is a planar gate electrode, example embodiments are not limited thereto, and the circuit gate structure 210 may correspond to a three-dimensional transistor. Still further, the number of and/or the arrangement of and/or the number of levels of the wiring structure 230 is not limited to that illustrated in FIG. 16D.

The second bonding insulating layer 266 may include silicon oxide or SiCN. The second bonding insulating layer 266 and the first bonding insulating layer 166 may be bonded to each other by forming a covalent bond.

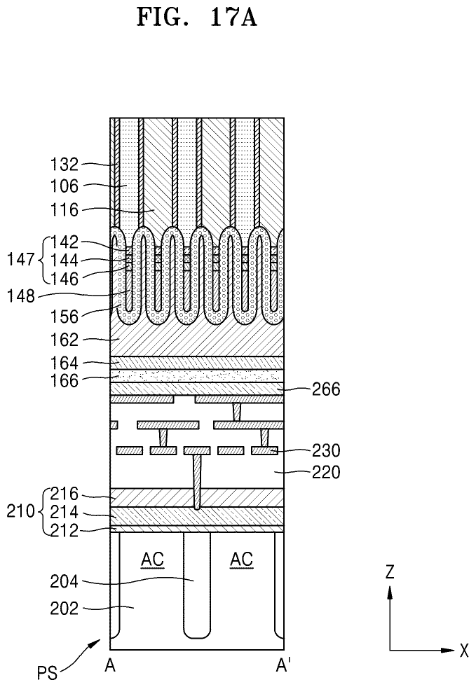

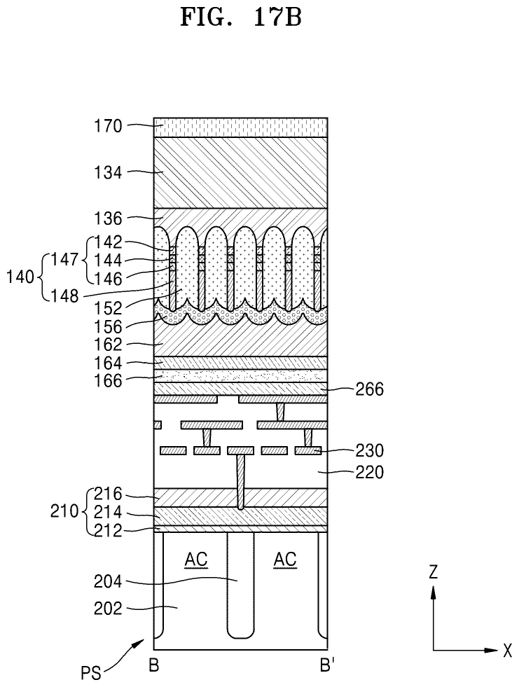

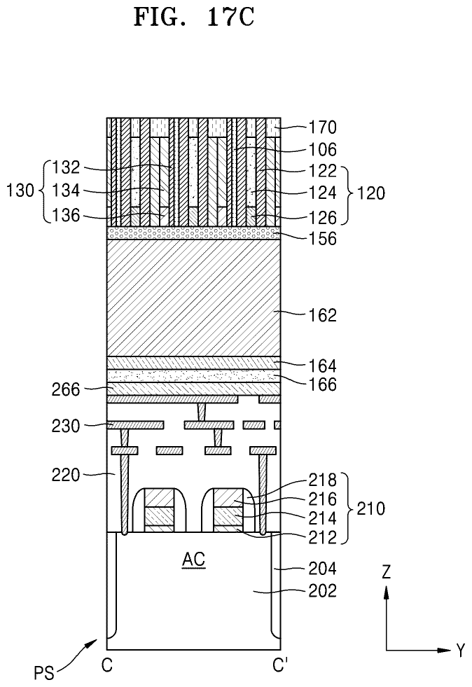

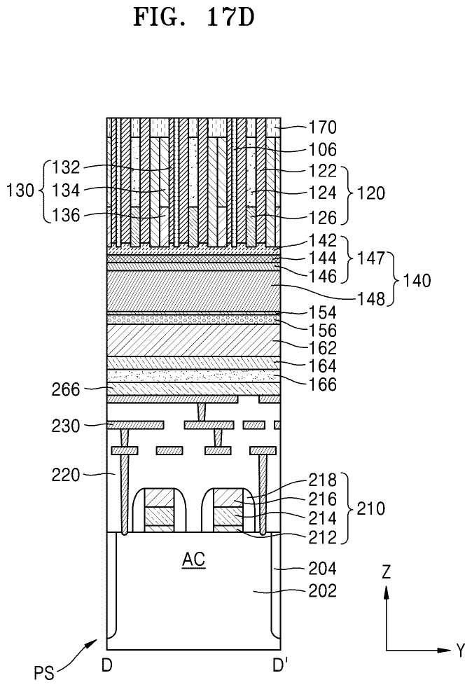

Referring to FIGS. 16A to 16D and 17A to 17D together, the base substrate 102 and the base insulating layer 104 are removed to expose the plurality of channel layers 106 and a plurality of word lines 134. In a process of removing the base substrate 102 and the base insulating layer 104, a portion of the plurality of back gate structures 120 may be removed together. For example, in the process of removing the base substrate 102 and the base insulating layer 104, a portion of the plurality of back gate insulating layers 122 may be removed to expose a plurality of back gate lines 124. In some example embodiments, the process of removing the base structures 120 may include a back-grinding and/or an etch-back process; example embodiments are not limited thereto.

Then, after upper portions of the plurality of back gate lines 124 and the plurality of word lines 134 are removed, a buried capping layer 170 filling the upper portions of the plurality of back gate lines 124 and the plurality of word lines 134 is formed. For example, the buried capping layer 170 may include silicon nitride.

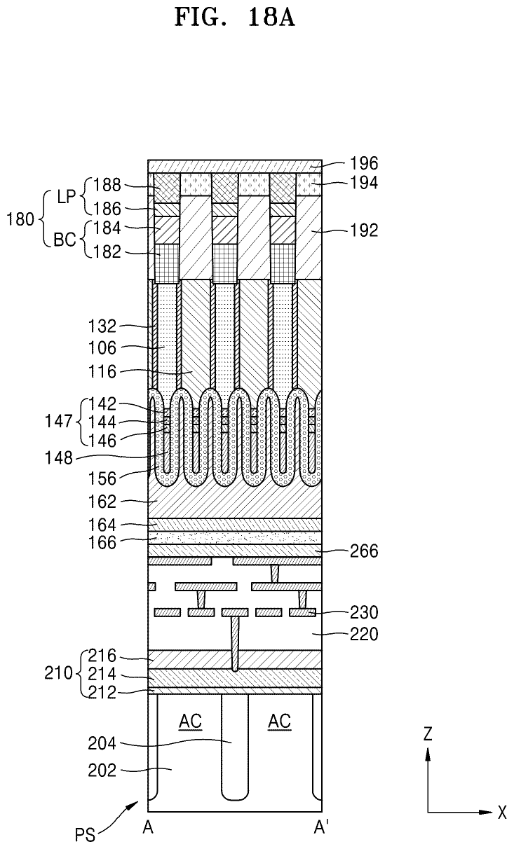

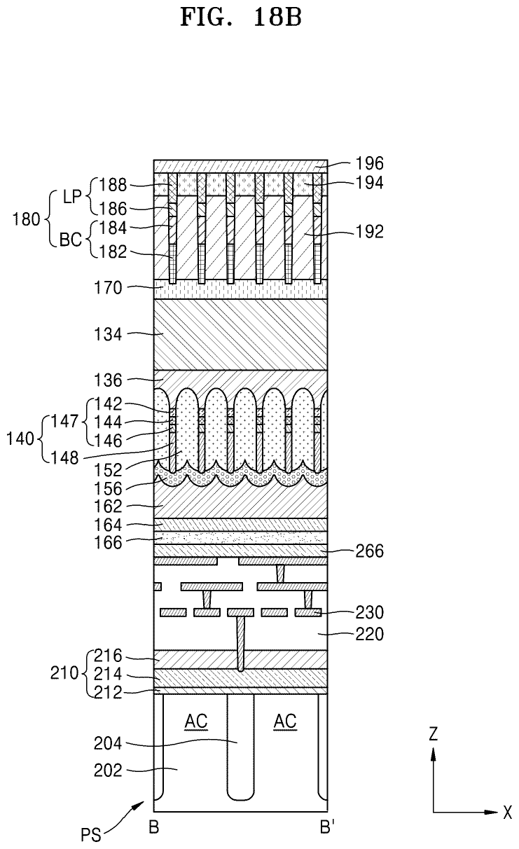

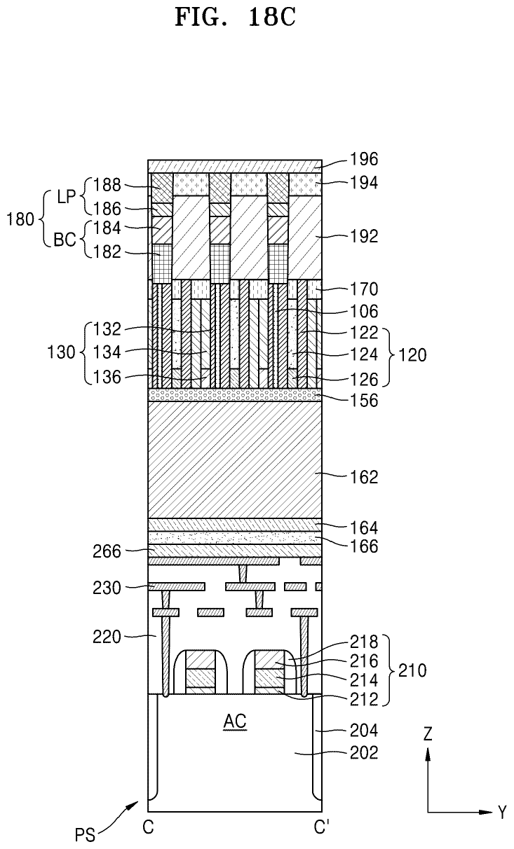

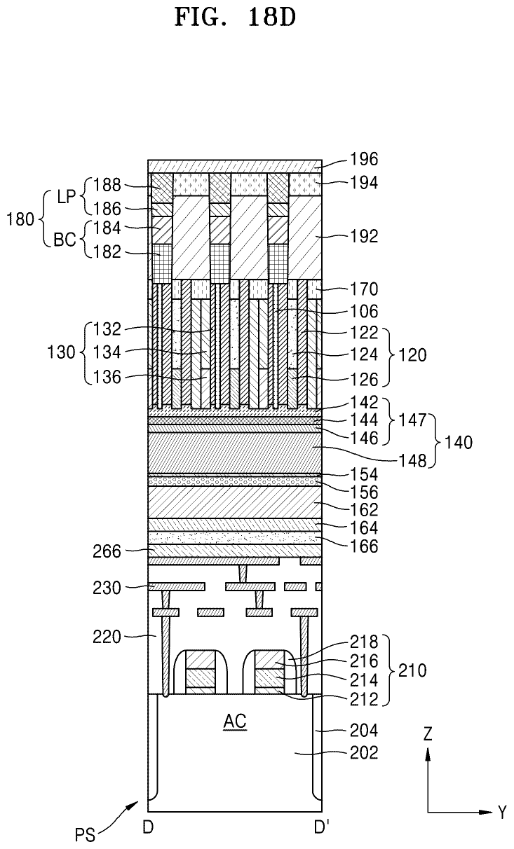

Referring to FIGS. 18A to 18D, a plurality of connection structures 180 are formed on the plurality of channel layers 106. The plurality of connection structures 180 may be surrounded by a first surrounding insulating layer 192 and a second surrounding insulating layer 194. Each of the plurality of connection structures 180 may include a conductive material, for example, at least one of a doped semiconductor material, metal, conductive metal nitride, conductive metal carbonitride, conductive metal carbide, metal silicide, conductive metal oxynitride, conductive metal oxide, and a two-dimensional (2D) material, but inventive concepts are not limited thereto.

Each of the plurality of connection structures 180 may include a lower connection structure BC and an upper connection structure LP on the lower connection structure BC. The lower connection structure BC and the upper connection structure LP, which correspond to each other, may be aligned with each other in the vertical direction (Z direction). The lower connection structure BC may have a stacked structure of a first semiconductor layer 182 and a second semiconductor layer 184. In some example embodiments, the first semiconductor layer 182 may include a monocrystalline semiconductor material, and the second semiconductor layer 184 may include a polycrystalline semiconductor material. For example, the first semiconductor layer 182 may be formed by epitaxially growing the channel layer 106 as a seed. For example, the first semiconductor layer 182 may include monocrystalline silicon, and the second semiconductor layer 184 may include polysilicon. In some example embodiments, the upper connection structure LP may have a stacked structure of a silicide layer 186 and a metal plug 188. For example, the silicide layer 186 may include WSiₓ, NiSiₓ, CoSiₓ, or NiPtSiₓ, and the metal plug 188 may include W, Mo, Au, Cu, Al, Ni, or Co. For example, the first surrounding insulating layer 192 may include silicon oxide, and the second surrounding insulating layer 194 may include silicon nitride.

An etch stop film 196 may be formed on the plurality of connection structures 180 and the second surrounding insulating layer 194. For example, the etch stop film 196 may include silicon nitride.

Referring to FIGS. 19A to 19D together, a plurality of memory structures, such as a plurality of memristors and/or a plurality of capacitor structures 300 penetrating the etch stop film 196 to be electrically connected to the plurality of connection structures 180 may be formed to form the semiconductor memory device 1. The plurality of capacitor structures 300 may be formed by sequentially stacking a plurality of lower electrodes 310, a capacitor dielectric layer 320, and an upper electrode 330. Each of the plurality of capacitor structures 300 may or may not have hysteresis behavior.

Each of the plurality of lower electrodes 310 may be electrically connected correspondingly to each of the plurality of connection structures 180. Each of the plurality of connection structures 180 may include the lower connection structure BC and the upper connection structure LP on the lower connection structure BC. The lower connection structure BC may be arranged toward the channel layer 106 to be electrically connected to the channel layer 106, and the upper connection structure LP may be arranged toward the lower electrode 310 to be electrically connected to the lower electrode 310.

Each of the plurality of lower electrodes 310 may have a column shape filled inside to have a circular horizontal cross section, for example, a pillar shape, but inventive concepts are not limited thereto. In some example embodiments, the plurality of lower electrodes 310 may each have a cylinder shape with a lower portion closed. In some example embodiments, the plurality of lower electrodes 310 may be arranged in a honeycomb shape that is arranged in a zigzag manner with respect to the first horizontal direction (X direction) or the second horizontal direction (Y direction). In some other embodiments, the plurality of lower electrodes 310 may be arranged in a matrix form that is arranged in a line in each of the first horizontal direction (X direction) and the second horizontal direction (Y direction). The plurality of lower electrodes 310 may include, for example, silicon doped with impurities, metal such as tungsten and/or copper, and/or conductive metal compound such as titanium nitride.

The capacitor dielectric layer 320 may conformally cover surfaces of the plurality of lower electrodes 310. In some example embodiments, the capacitor dielectric layer 320 may be integrally formed to cover the plurality of lower electrodes 310 together within a certain arca. The capacitor dielectric layer 320 may include, for example, TaO, TaAlO, TaON, AIO, AlSiO, HfO, HfSiO, ZrO, ZrSiO, TiO, TiAlO, BST((Ba,Sr)TiO), STO(SrTiO), BTO(BaTiO), PZT(Pb,Zr,Ti)O), (Pb,La)(Zr,Ti)O, Ba(Zr,Ti)O, Sr(Zr,Ti)O, or a combination thereof.

The upper electrode 330 may include, for example, W, Ru, RuO, Pt, PtO, Ir, IrO, SRO(SrRuO), BSRO((Ba,Sr)RuO), CRO(CaRuO), BaRuO, La(Sr,Co) O, or the like. In some example embodiments, the upper electrode 330 may include a metal material. For example, the upper electrode 330 may include W. In some example embodiments, the upper electrode 330 may further include, in addition to the metal material, at least one of a doped semiconductor material layer and an interface layer to have a stacked structure thereof. The doped semiconductor material layer may include at least one of doped polysilicon or doped polycrystalline silicon germanium. The interface layer may include, for example, at least one of metal oxide, metal nitride, metal carbide, and metal silicide.

The semiconductor memory device 1 includes the plurality of bit line structures 140 on the peripheral circuit structure PS, a transistor structure including the plurality of back gate structures 120 on the plurality of bit line structures 140, the plurality of word line structures 130, and the plurality of channel layers 106, the plurality of capacitor structures 300 on the transistor structure, and the plurality of connection structures 180 electrically connecting the plurality of channel layers 106 to the plurality of capacitor structures 300. The plurality of channel layers 106 may be electrically connected to the plurality of lower electrodes 310 through the plurality of connection structures 180. The plurality of word line structures 130 and the plurality of channel layers 106 of the transistor structure configure a plurality of transistors. The plurality of transistors may each be or may each correspond to a VCT.

The plurality of back gate structures 120 may each include the back gate insulating layer 122, the back gate line 124, and the back gate capping layer 126. Each of the plurality of word line structures 130 includes the gate insulating layer 132, the word line 134, and the word line capping layer 136. The plurality of back gate lines 124 and the plurality of word lines 134 may be spaced apart from each other and alternately arranged in the second horizontal direction (Y direction). The plurality of back gate lines 124 and the plurality of word lines 134 may extend in parallel to each other in the first horizontal direction (X direction).

The plurality of channel layers 106 may be arranged in a column (e.g., a horizontal column) in the first horizontal direction (X direction) between one word line 134 and one back gate line 124, which are adjacent to each other among the plurality of word lines 134 and the plurality of back gate lines 124. The plurality of channel layers 106 may extend in the vertical direction (Z direction). Channel layers 106 arranged between a pair of back gate lines 124 adjacent to each other among the plurality of back gate lines 124 may be arranged in a zigzag manner in the first horizontal direction (X direction). For example, the channel layers 106 between the pair of back gate lines 124 among the plurality of back gate lines 124 may be arranged in a pair of columns extending in the first horizontal direction (X direction), and the channel layers 106 arranged to form a pair of columns between the pair of back gate lines 124 may be alternately arranged in a pair of columns in a zigzag manner in the first horizontal direction (X direction).

The plurality of bit line structures 140 may each include the bit line 147 and the insulating capping line 148 covering the bit line 147. The plurality of bit line structures 140 may be spaced apart from each other in the first horizontal direction (X direction), and may extend in parallel to each other in the second horizontal direction (Y direction). The plurality of bit lines 147 and the plurality of insulating capping lines 148 may be spaced apart from each other in the first horizontal direction (X direction), and may extend in parallel to each other in the second horizontal direction (Y direction). The plurality of bit lines 147 may be electrically connected to the plurality of channel layers 106.

In the semiconductor memory device 1, the plurality of back gate lines 124 and the plurality of word lines 134 may be alternately arranged in the second horizontal direction (Y direction), channel layers 106 may be arranged between the back gate line 124 and the word line 134, which are adjacent to each other among the plurality of back gate lines 124 and the plurality of word lines 134, in a column in the first horizontal direction (X direction), and each of the plurality of bit lines 147 may extend in the second horizontal direction (Y direction) and may be electrically connected to a different one of the channel layers 106 arranged in a column in the first horizontal direction (X direction). Accordingly, the semiconductor memory device 1 according to various example embodiments may have a relatively high degree of integration in the second horizontal direction (Y direction), and thus the degree of integration of the semiconductor memory device 1 may increase. There may be an improvement in one or more of speed, manufacturability, yield, or reliability.

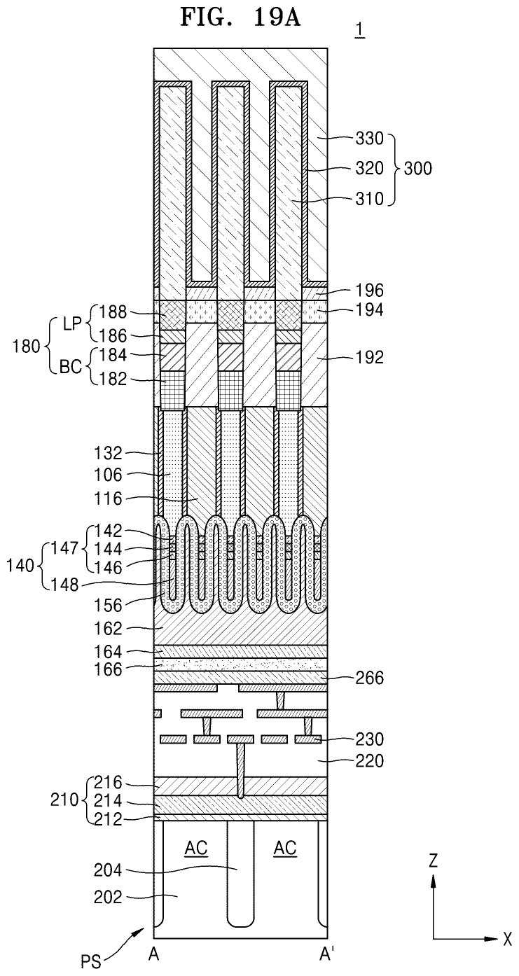

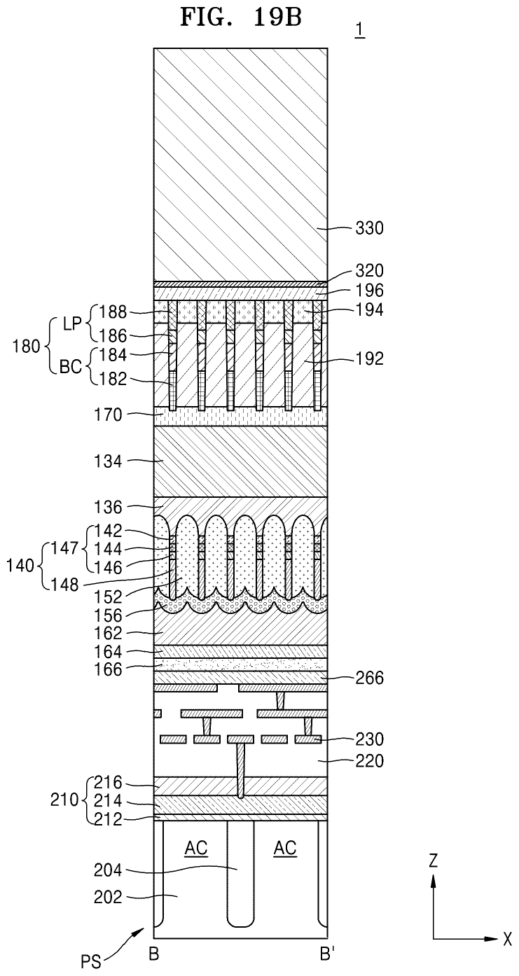

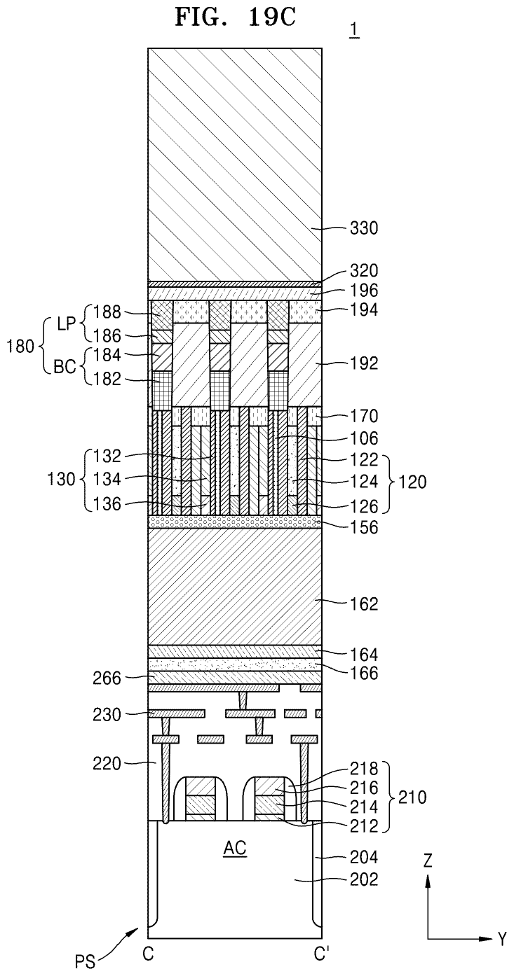

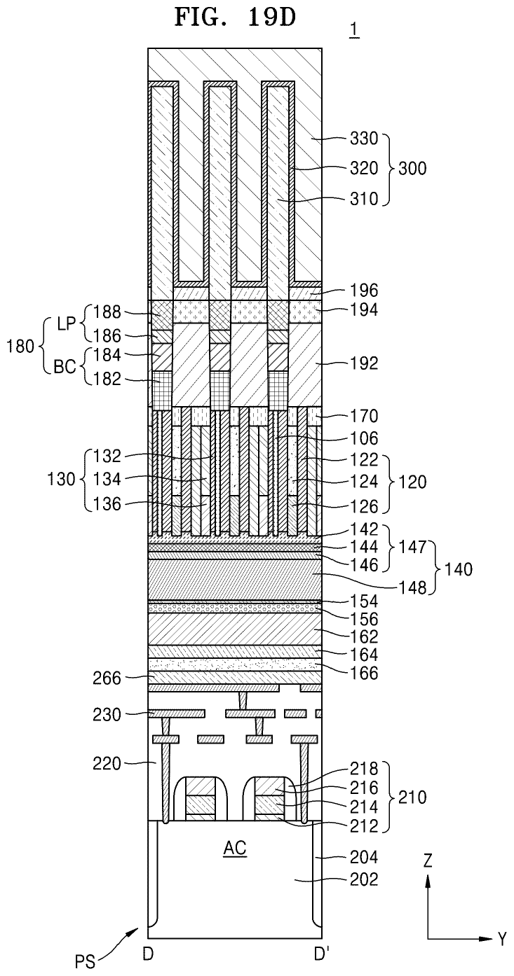

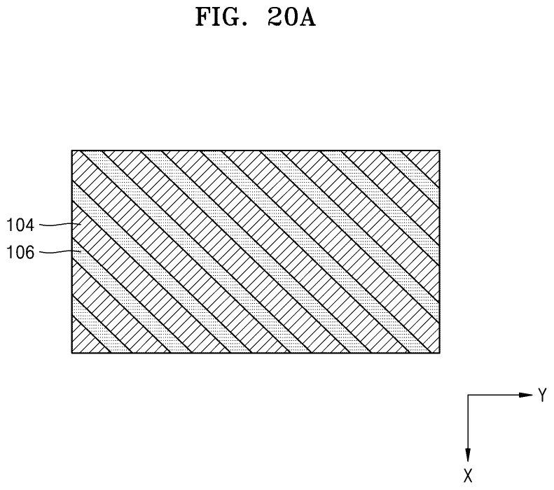

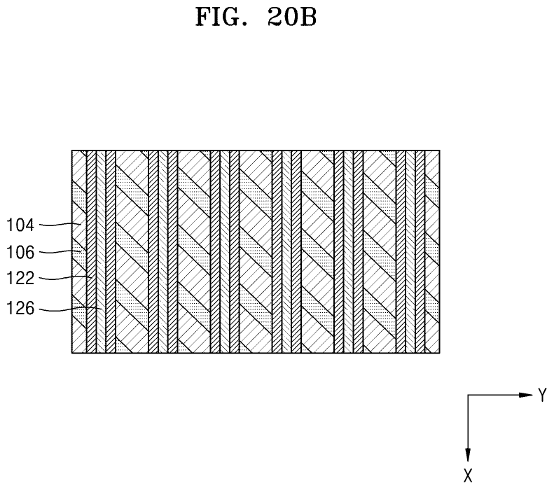

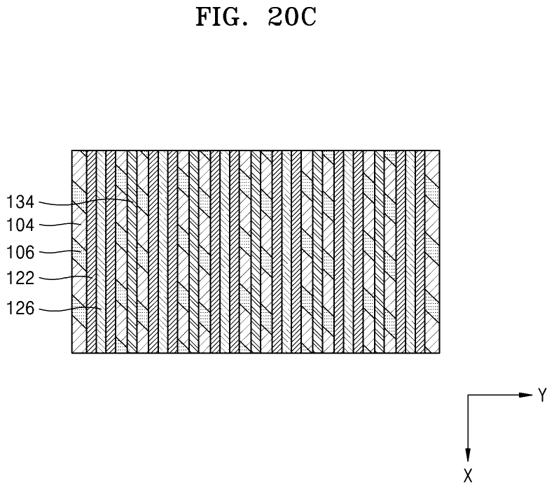

FIGS. 20A to 20C, 21A to 21C, 22A to 22C, 23A to 23C, and 24A to 24C are plan views each illustrating main components of a semiconductor memory device according to various example embodiments.

Referring to FIGS. 20A, the plurality of channel layers 106 shown in FIGS. 3 and 4A to 4D may be formed to extend in parallel to each other in a diagonal direction with respect to the first horizontal direction (X direction) and the second horizontal direction (Y direction). The base insulating layer 104 may be exposed on bottom surfaces of spaces between the plurality of channel layers 106.

Referring to FIGS. 20B, two back gate insulating layers 122 relatively closely adjacent to each other among the plurality of back gate insulating layers 122 may form or be arranged as a pair. The back gate line 124 (refer to FIGS. 10C and 10D) and the back gate capping layer 126 covering the back gate line 124 may be arranged between the two back gate insulating layers 122 forming a pair. The back gate line 124 and the back gate capping layer 126 may extend in the first horizontal direction (X direction). The two back gate insulating layers 122 forming a pair may extend in the first horizontal direction (X direction) along both sides of the back gate line 124 in the second horizontal direction (Y direction). The plurality of channel layers 106 may be positioned between two back gate insulating layers 122 relatively distantly adjacent to each other among the plurality of back gate insulating layers 122.

Referring to FIG. 20C, the plurality of word lines 134 may be arranged between the two back gate insulating layers 122 relatively distantly adjacent to each other among the plurality of back gate insulating layers 122. The plurality of word lines 134 may be spaced apart from each other in the second horizontal direction (Y direction), and may extend in parallel to each other in the first horizontal direction (X direction).

One back gate line 124 (refer to FIGS. 10C and 10D), the back gate capping layer 126 covering the back gate line 124, and a pair of back gate insulating layers 122 covering both side surfaces of the back gate line 124 and extending in the first horizontal direction (X direction) may be between a pair of word lines 134 adjacent to each other in the second horizontal direction (Y direction).

The plurality of back gate lines 124 and the plurality of word lines 134 may be alternately arranged in the second horizontal direction (Y direction). In some example embodiments, the plurality of back gate lines 124 and the plurality of word lines 134 may be alternately arranged with a constant interval in the second horizontal direction (Y direction). The channel layers 106 may be arranged between the back gate line 124 and the word line 134, which are adjacent to each other among the plurality of back gate lines 124 and the plurality of word lines 134, to form a column in the first horizontal direction (X direction). Between the pair of back gate lines 124 among the plurality of back gate lines 124, the channel layers 106 may be arranged in a pair of columns extending in the first horizontal direction (X direction) and spaced apart from each other in the second horizontal direction (Y direction) with the word line 134 as a center, and the channel layers 106 arranged in a pair of columns between the pair of back gate lines 124 may be alternately arranged in the pair of columns in a zigzag manner in the first horizontal direction (X direction).

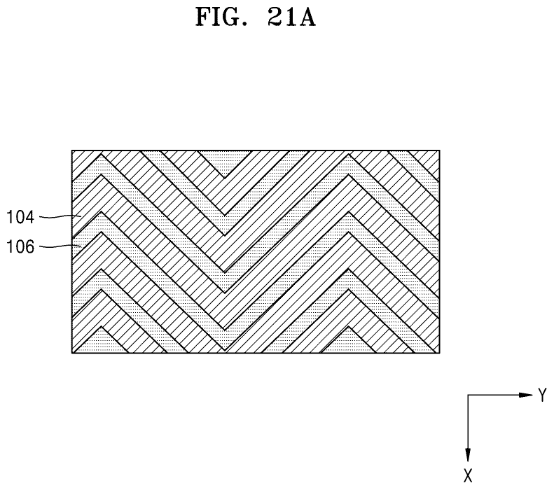

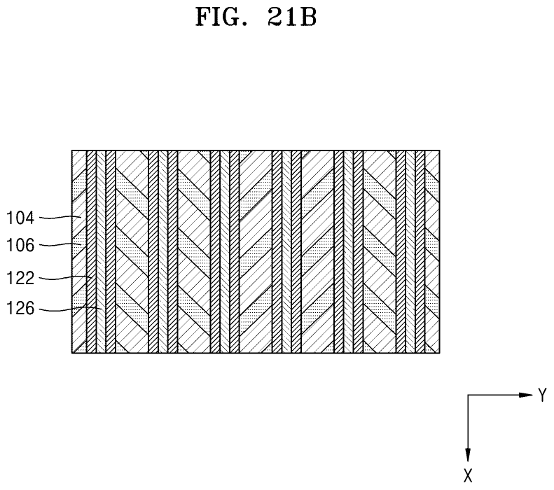

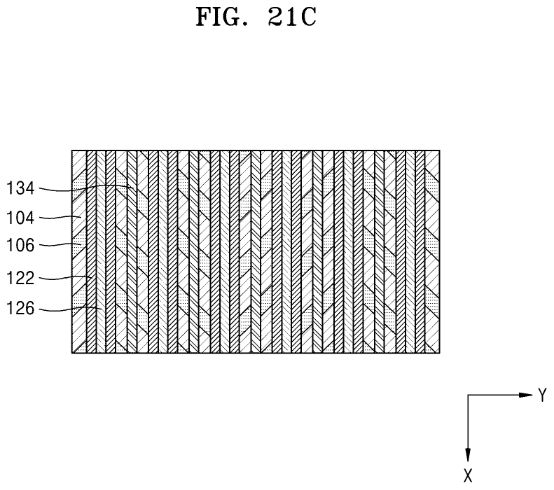

Referring to FIGS. 21A to 23C together, the plurality of channel layers 106 may be formed to extend with a wavy shape in a plan view. The base insulating layer 104 may be exposed on bottom surfaces of spaces between the plurality of channel layers 106.

A portion of the channel layer 106 extending without bending in FIG. 21A may be separated into two by one back gate line 124 (refer to FIGS. 10C and 10D) and one back gate capping layer 126 covering the one back gate line 124 in FIG. 21B, and may be separated again into two by one word line 134 in FIG. 21C to be separated into four channel layers 106 in total.

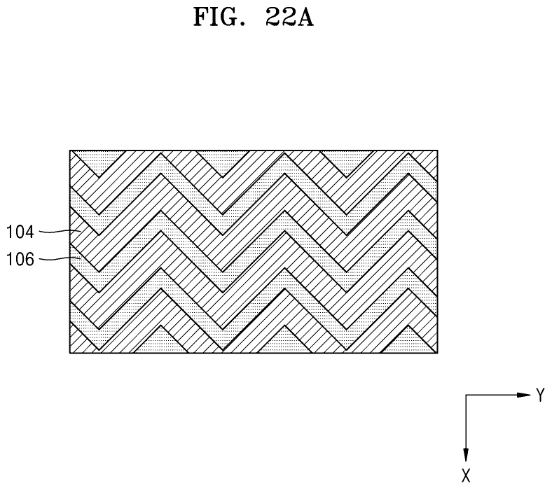

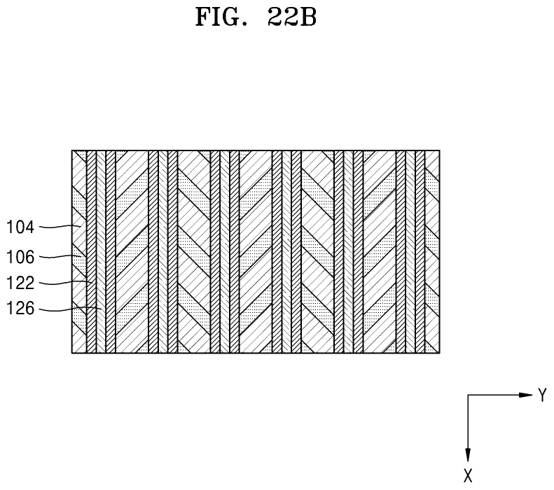

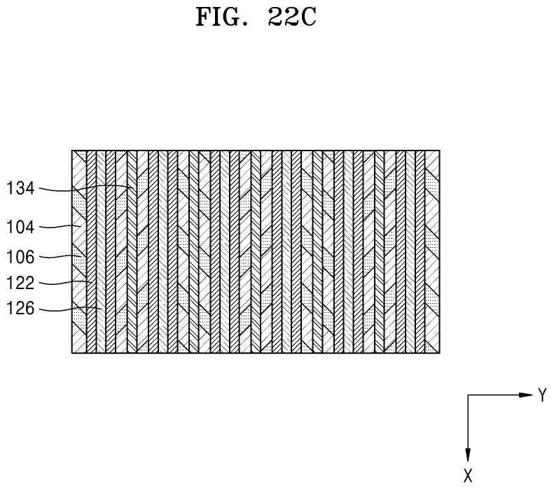

Portions of the channel layer 106 extending without bending in FIG. 22A may respectively be separated by one back gate line 124 (refer to FIGS. 10C and 10D) and one back gate capping layer 126 covering the one back gate line 124 in FIG. 22B, and may be separated into two by one word line 134 in FIG. 22C to be separated into two channel layers 106 in total.

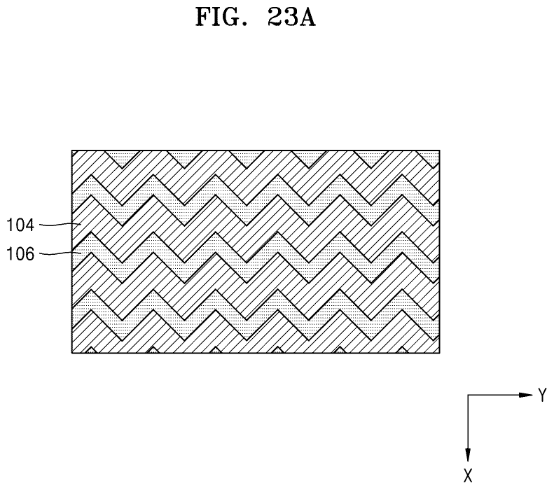

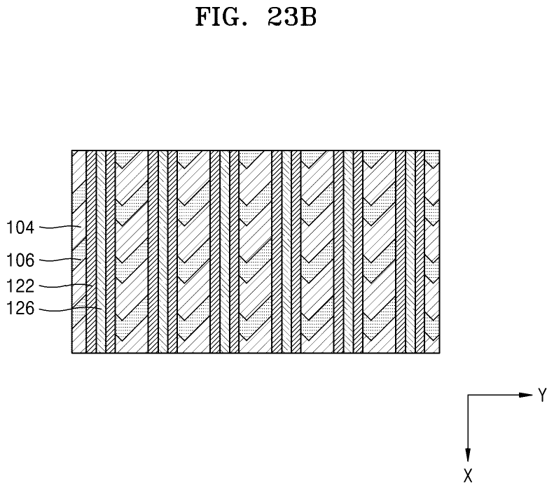

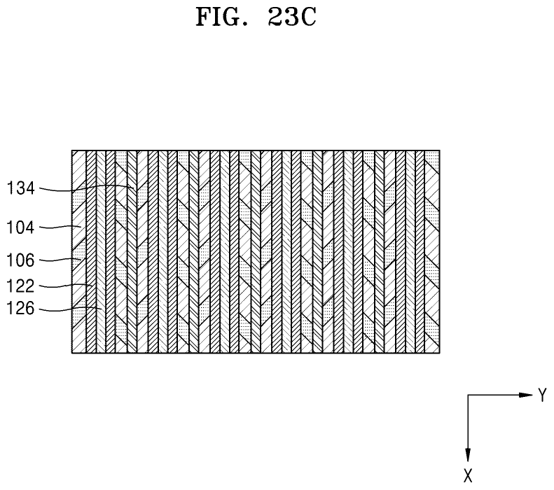

Portions of the channel layer 106 extending without bending in FIG. 23A may be separated by one back gate line 124 (refer to FIGS. 10C and 10D) and one back gate capping layer 126 covering the one back gate line 124 shown in FIG. 23B and one word line 134 shown in FIG. 23C to be respectively separated into one channel layer 106.

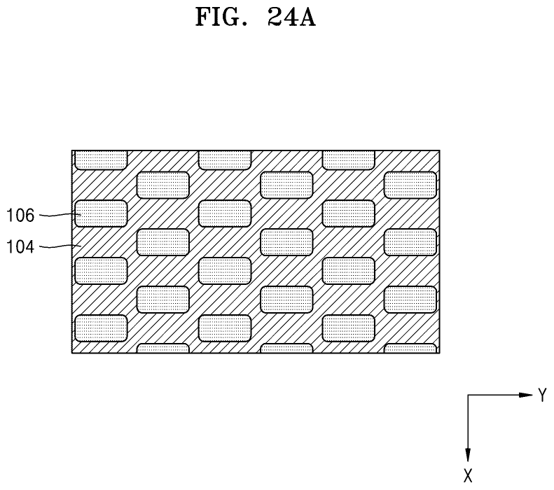

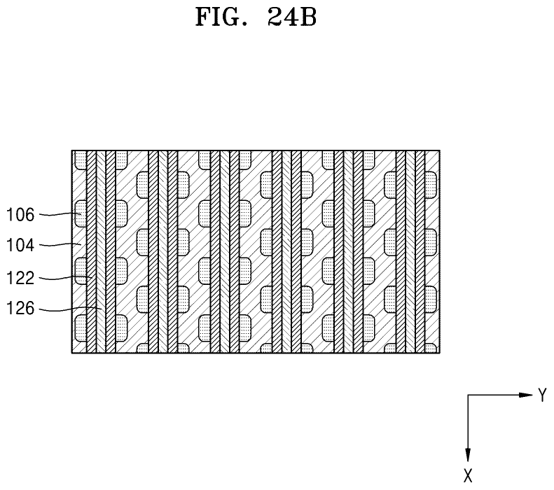

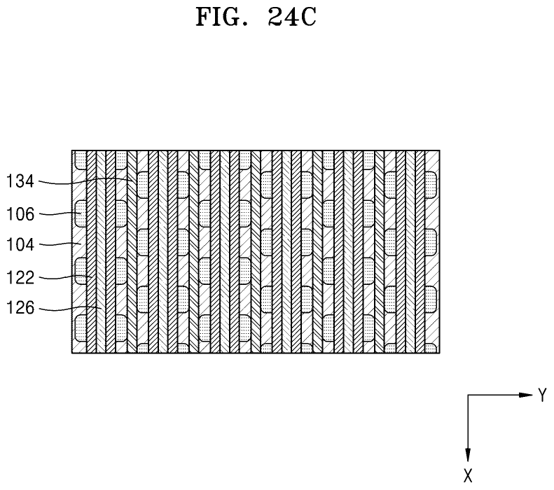

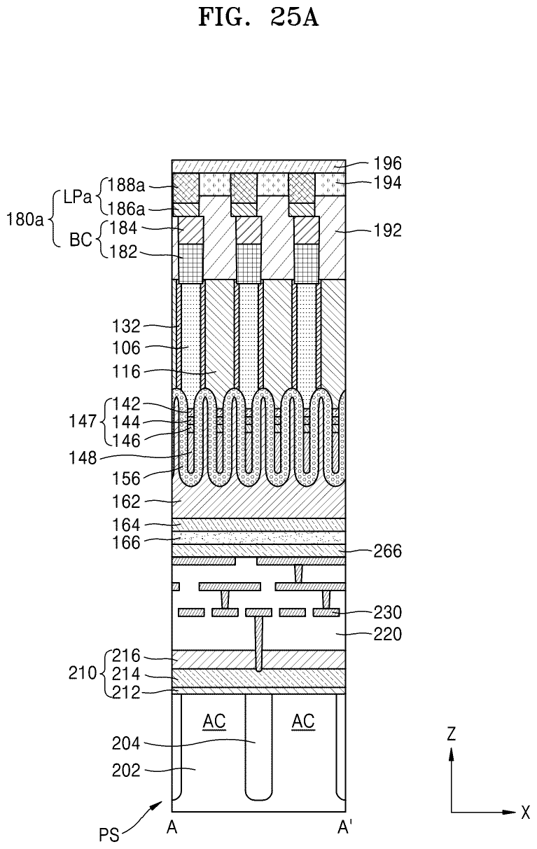

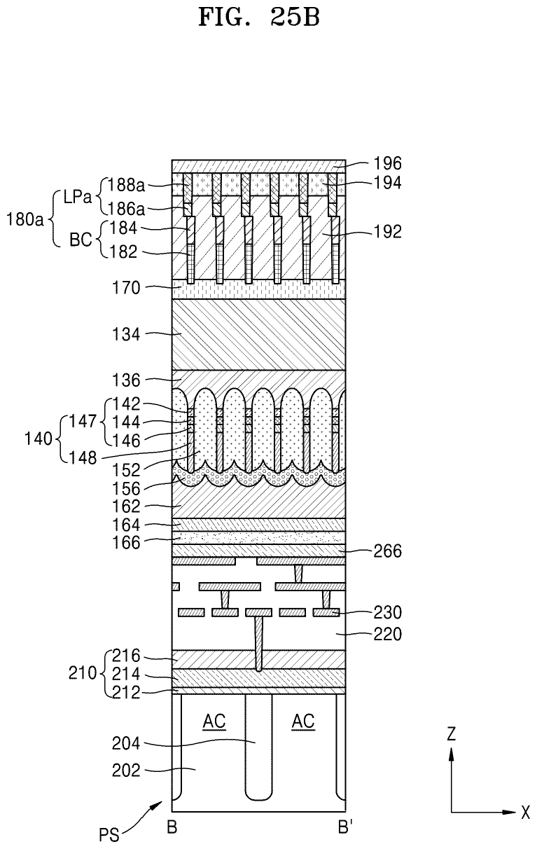

Referring to FIGS. 24A to 24C together, the plurality of channel layers 106 may be arranged in a honeycomb shape that is arranged in a zigzag manner in the first horizontal direction (X direction) or the second horizontal direction (Y direction). Each of the plurality of channel layers 106 shown in FIG. 24A may be separated into two by one back gate line 124 (refer to FIGS. 10C and 10D) and one back gate capping layer 126 covering the one back gate line 124 shown in FIG. 24B, and the plurality of back gate insulating layers 122 shown in FIG. 24A may each be separated into two channel layers 106 as shown in FIG. 24C.

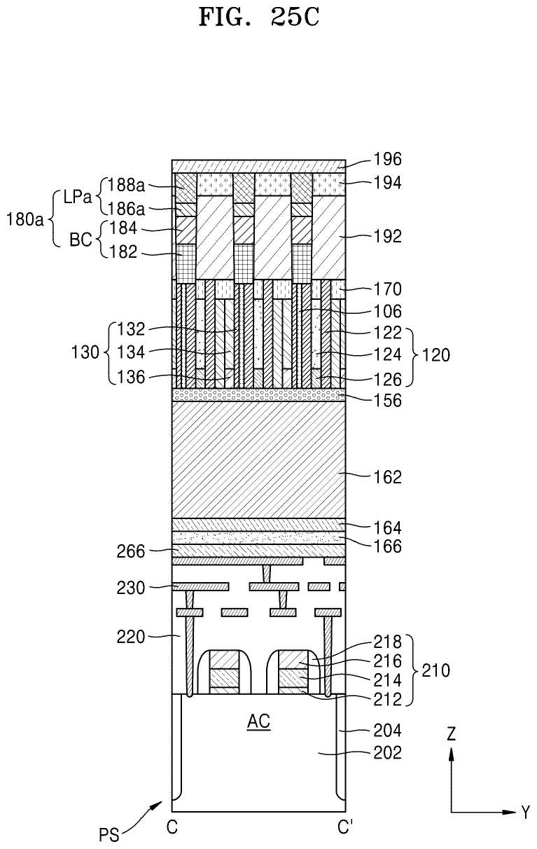

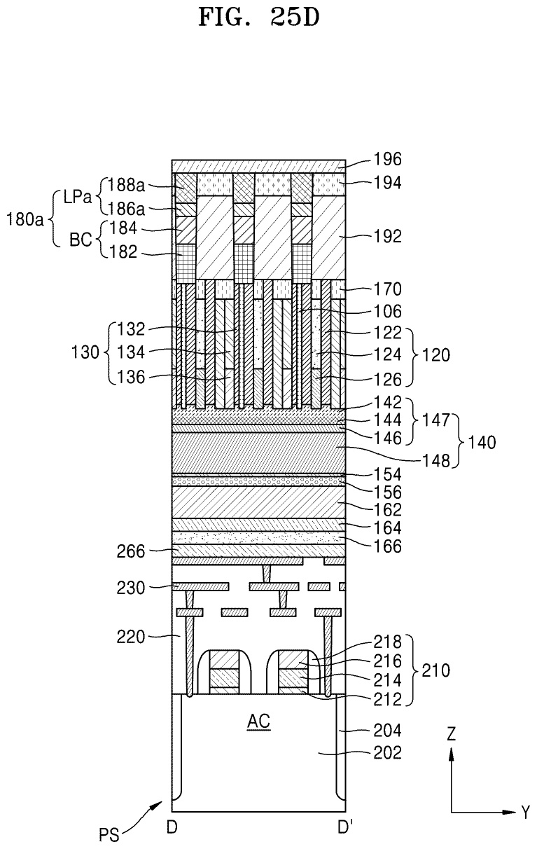

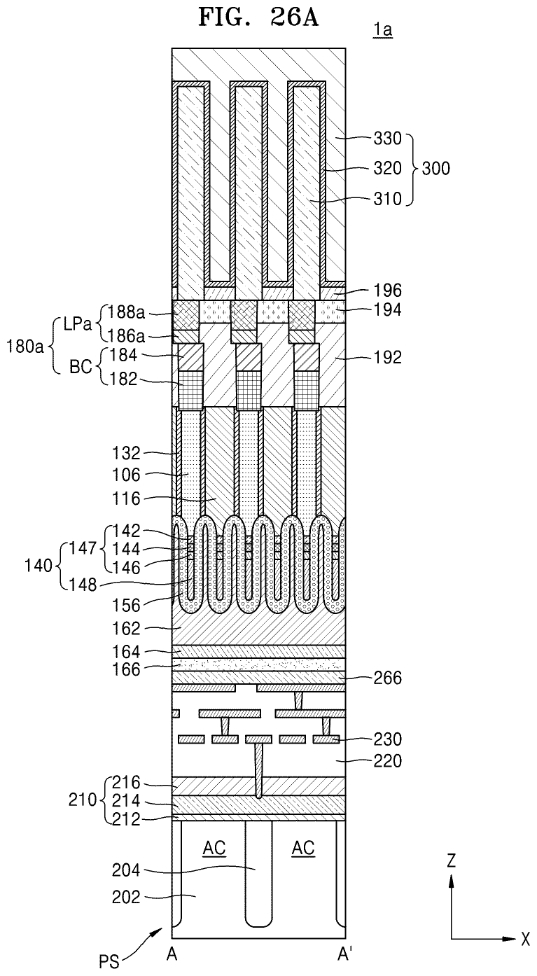

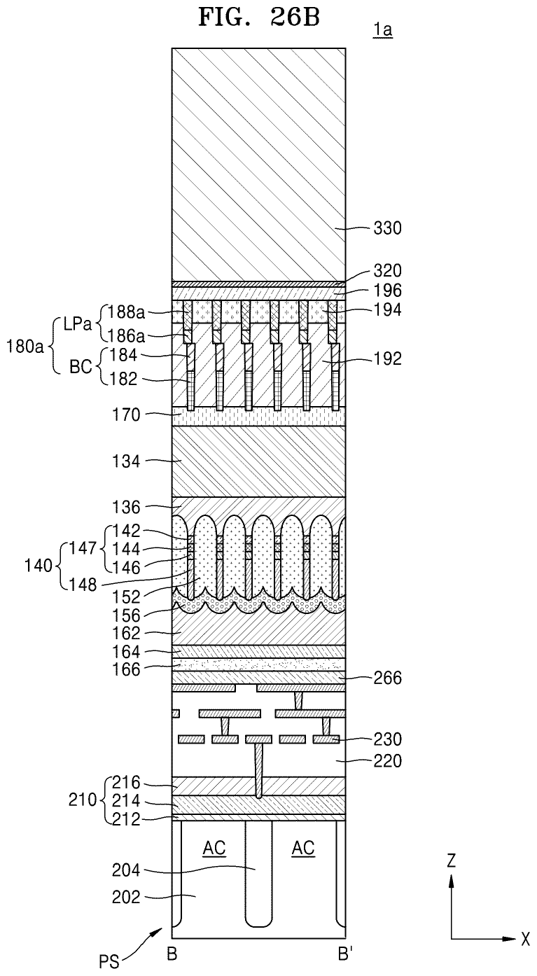

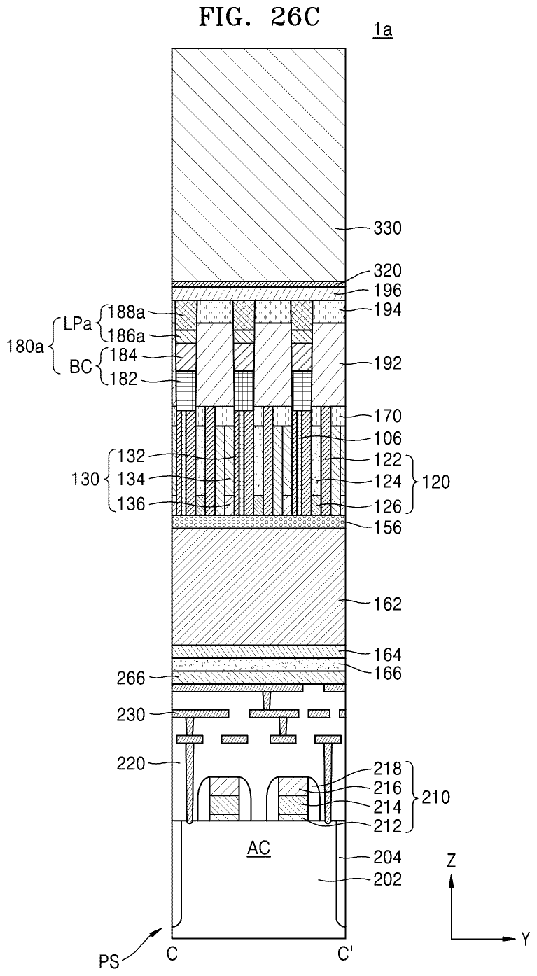

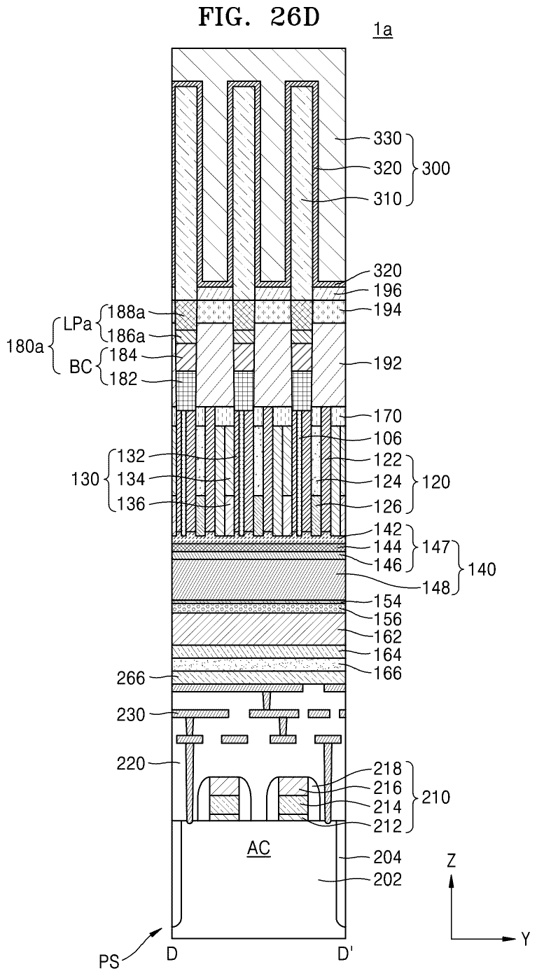

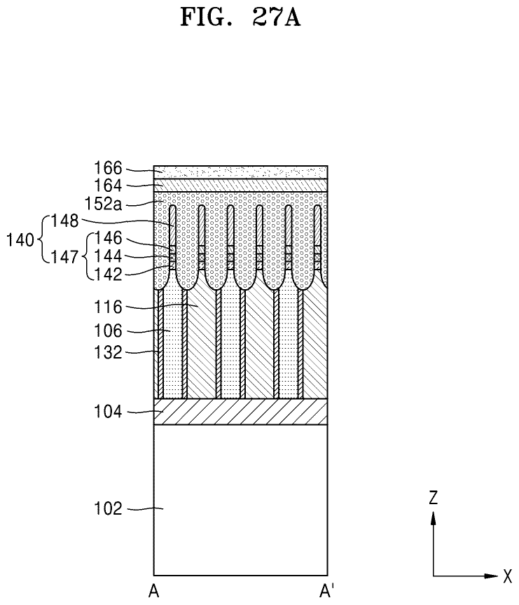

FIGS. 25A to 25D are diagrams for explaining a method of manufacturing a semiconductor memory device according to various example embodiments, and FIGS. 26A to 26D are cross-sectional views each illustrating a semiconductor memory device according to various example embodiments. In particular, FIGS. 25A and 26A are cross-sectional views taken along the line A-A′ of FIG. 13, FIGS. 25B and 26B are cross-sectional views taken along the line taken along the line B-B′ of FIG. 13, FIGS. 25C and 26C are cross-sectional views taken along the line C-C′ of FIG. 13, and FIGS. 25D and 26D are cross-sectional views taken along the line D-D′ of FIG. 13.

Referring to FIGS. 25A to 25D together, a plurality of connection structures 180a are formed on the plurality of channel layers 106. The plurality of connection structures 180a may be surrounded by the first surrounding insulating layer 192 and the second surrounding insulating layer 194. The plurality of connection structures 180a may each include the lower connection structure BC and an upper connection structure LPa on the lower connection structure BC. The lower connection structure BC may have a stacked structure of the first semiconductor layer 182 and the second semiconductor layer 184. In some example embodiments, the upper connection structure LPa may have a stacked structure of a silicide layer 186a and a metal plug 188a. For example, the silicide layer 186a may include WSiₓ, NiSiₓ, CoSiₓ, or NiPtSiₓ, and the metal plug 188a may include W, Mo, Au, Cu, Al, Ni, or Co. The upper connection structure LPa electrically connected correspondingly to the lower connection structure BC may be shifted from the lower connection structure BC in a horizontal direction. FIGS. 25A to 25D show that the upper connection structure LPa is shifted from the lower connection structure BC in the first horizontal direction (X direction), but inventive concepts are not limited thereto. In some example embodiments, the upper connection structure LPa may be shifted from the lower connection structure BC in the second horizontal direction (Y direction). In some other embodiments, the upper connection structure LPa may be shifted from the lower connection structure BC in each of the first horizontal direction (X direction) and the second horizontal direction (Y direction), that is, a diagonal direction with respect to the first horizontal direction (X direction) and the second horizontal direction (Y direction).

Referring to FIGS. 26A to 26D together, the plurality of capacitor structures 300 penetrating the etch stop film 196 to be electrically connected to the plurality of connection structures 180a may be formed to form a semiconductor memory device 1a. The plurality of capacitor structures 300 may be formed by sequentially stacking the plurality of lower electrodes 310, the capacitor dielectric layer 320, and the upper electrode 330. Each of the plurality of lower electrodes 310 may be electrically connected correspondingly to each of the plurality of connection structures 180a.

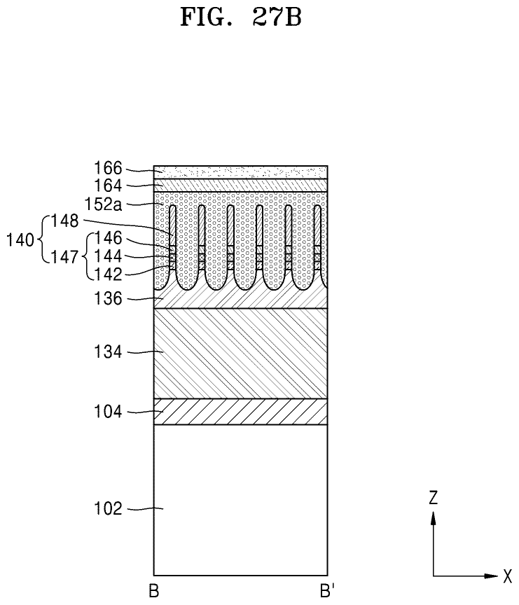

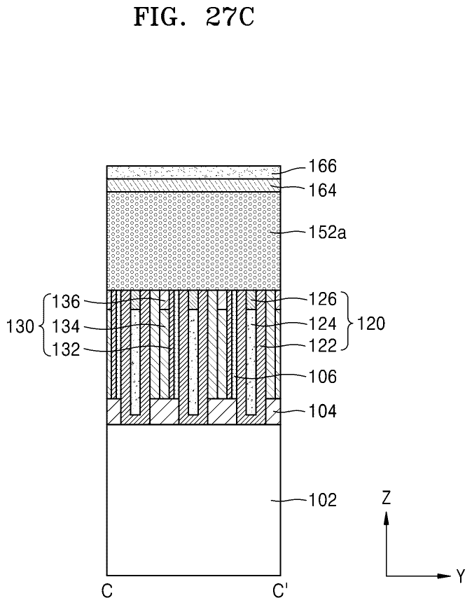

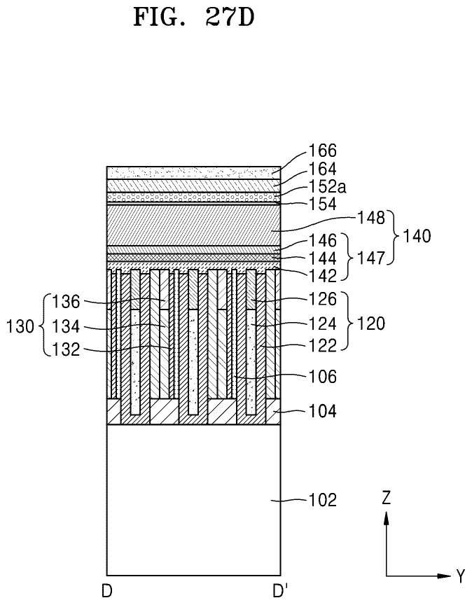

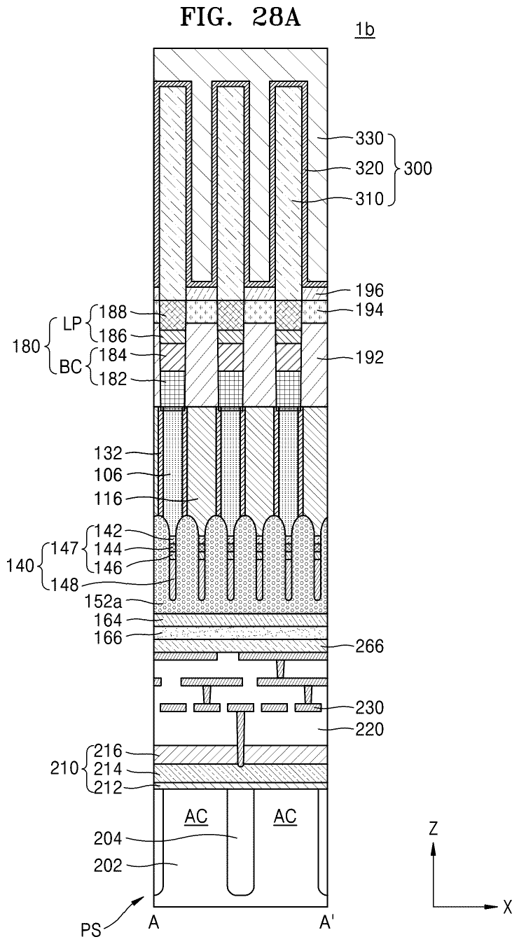

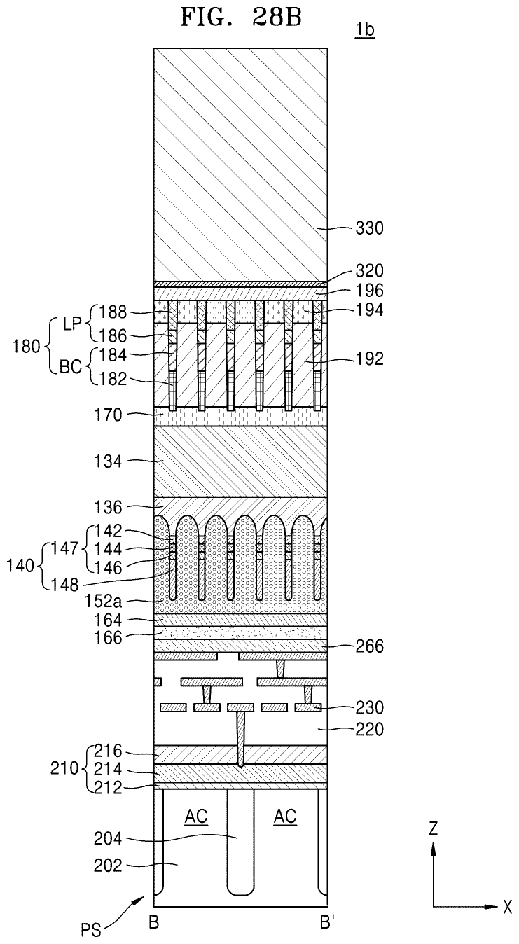

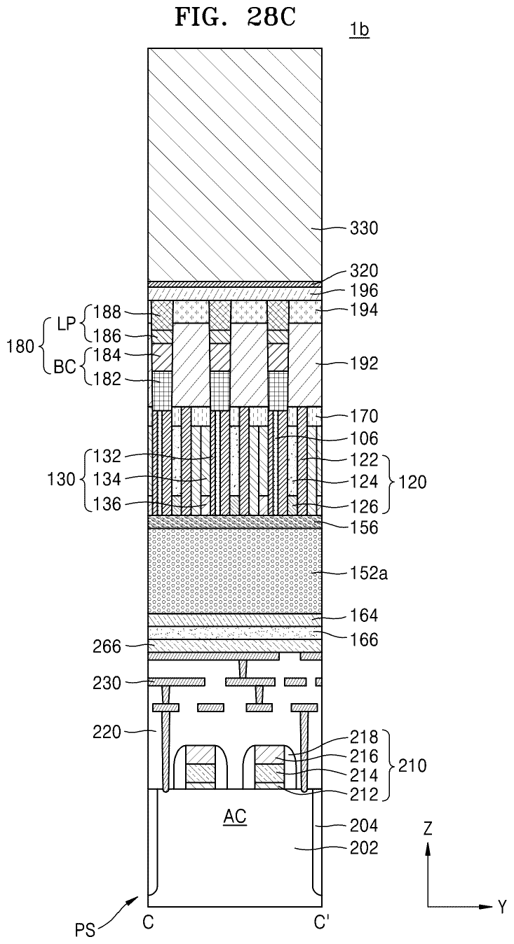

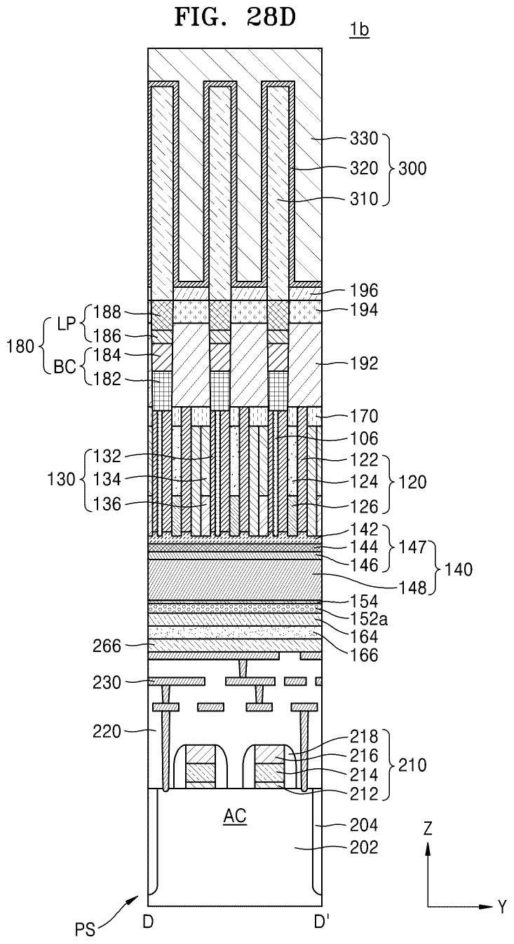

FIGS. 27A to 27D are diagrams for explaining a method of manufacturing a semiconductor memory device according to various example embodiments, and FIGS. 28A to 28D are cross-sectional views each illustrating a semiconductor memory device according to various example embodiments. In particular, FIGS. 27A and 28A are cross-sectional views taken along the line A-A′ of FIG. 13, FIGS. 27B and 28B are cross-sectional views taken along the line taken along the line B-B′ of FIG. 13, FIGS. 27C and 28C are cross-sectional views taken along the line C-C′ of FIG. 13, and FIGS. 27D and 28D are cross-sectional views taken along the line D-D′ of FIG. 13.

Referring to FIGS. 27A to 27D together, instead of forming the plurality of filling insulating layers 152, the cover insulating layer 156, and the shield conductive layer 162 as shown in FIGS. 13 and 14A to 14D, a filling insulating layer 152a filling a portion of each of spaces between the plurality of bit line structures 140 may be formed, and the protective insulating layer 164 covering the filling insulating layer 152a and the first bonding insulating layer 166 covering the protective insulating layer 164 may be sequentially formed.

Referring to FIGS. 28A to 28D together, the peripheral circuit structure PS, the buried capping layer 170, the plurality of connection structures 180, and the plurality of capacitor structures 300 may be formed to form a semiconductor memory device 1b.

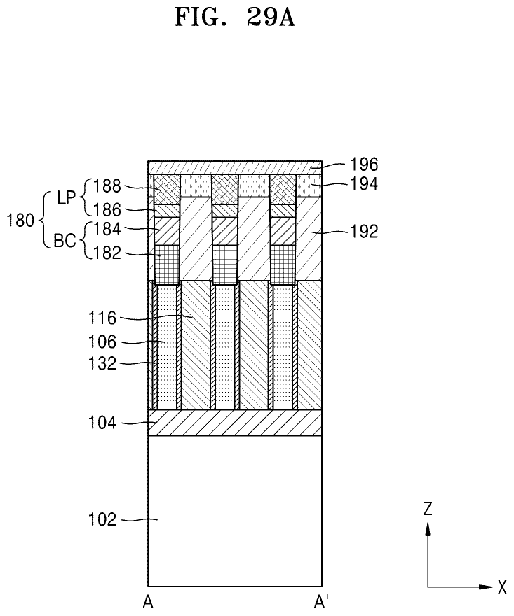

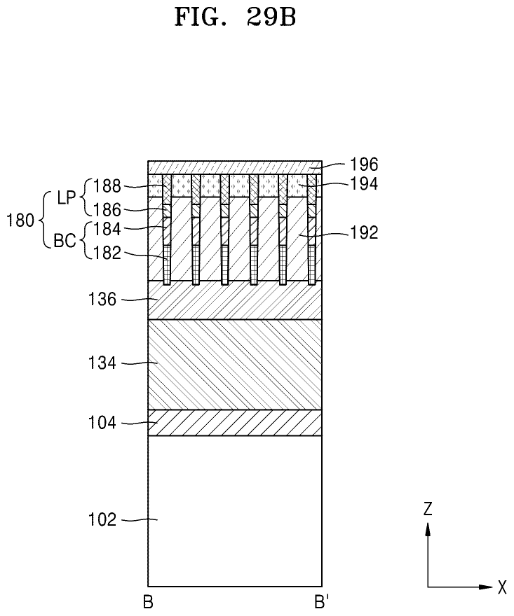

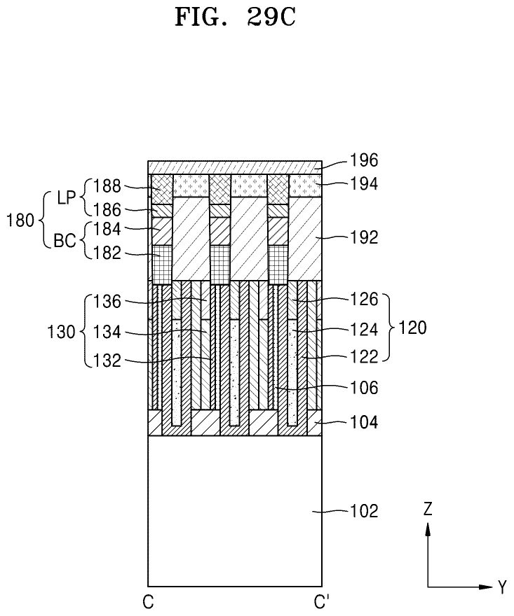

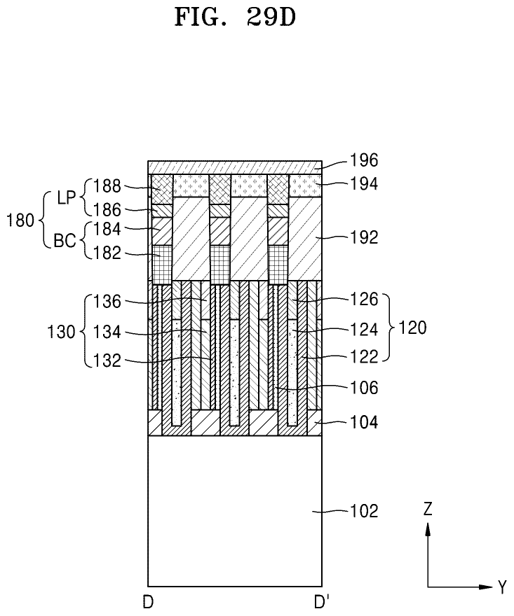

FIGS. 29A to 33D are diagrams for explaining a method of manufacturing a semiconductor memory device according to various example embodiments, and FIGS. 34A to 34D are cross-sectional views each illustrating a semiconductor memory device according to various example embodiments. In particular, FIGS. 29A, 30A, 31A, 32A, 33A, and 34A are cross-sectional views taken along the line A-A′ of FIG. 13, FIGS. 29B, 30B, 31B, 32B, 33B, and 34B are cross-sectional views taken along the line B-B′ of FIG. 13, FIGS. 29C, 30C, 31C, 32C, 33C, and 34C are cross-sectional views taken along the line C-C′ of FIG. 13, and FIGS. 29D, 30D, 31D, 32D, 33D, and 34D are cross-sectional views taken along the line D-D′ of FIG. 13.

Referring to FIGS, 29A to 29D, the plurality of connection structures 180 are formed on a resultant in FIGS. 9 and 10A to 10D. The plurality of connection structures 180 may be surrounded by the first surrounding insulating layer 192 and the second surrounding insulating layer 194. Each of the plurality of connection structures 180 may include the lower connection structure BC and the upper connection structure LP on the lower connection structure BC. The etch stop film 196 may be formed on the plurality of connection structures 180 and the second surrounding insulating layer 194.

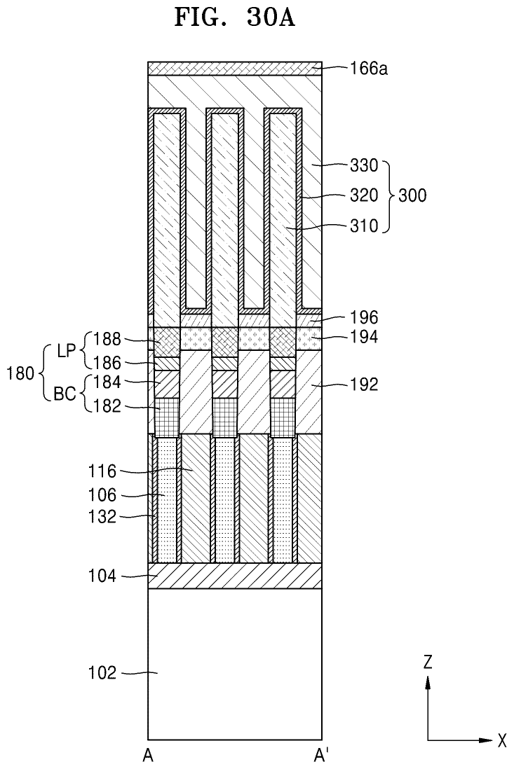

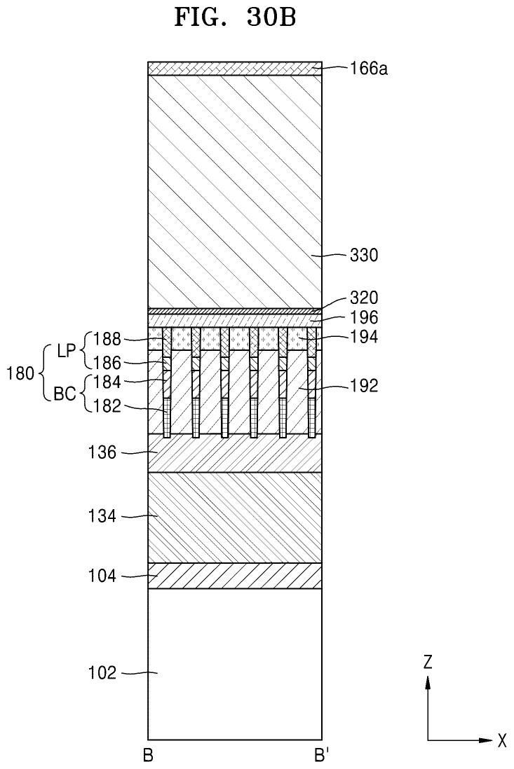

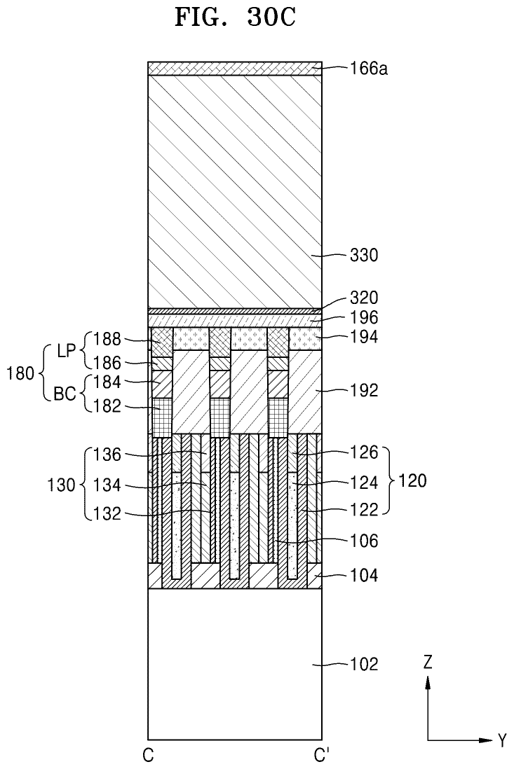

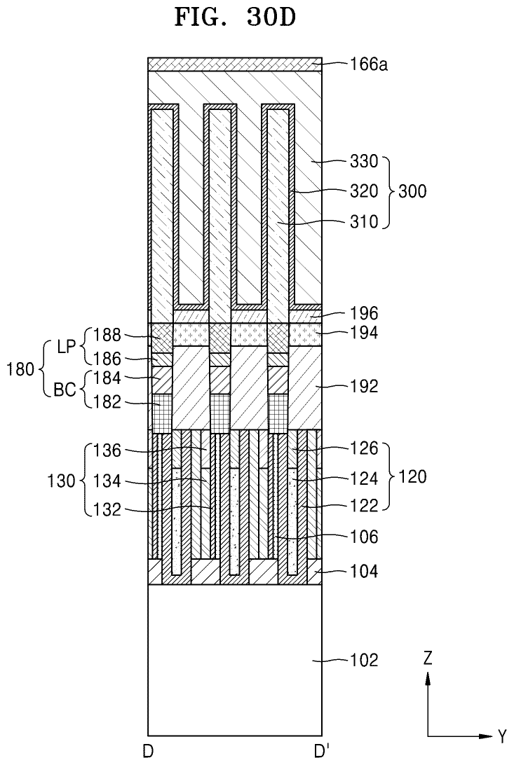

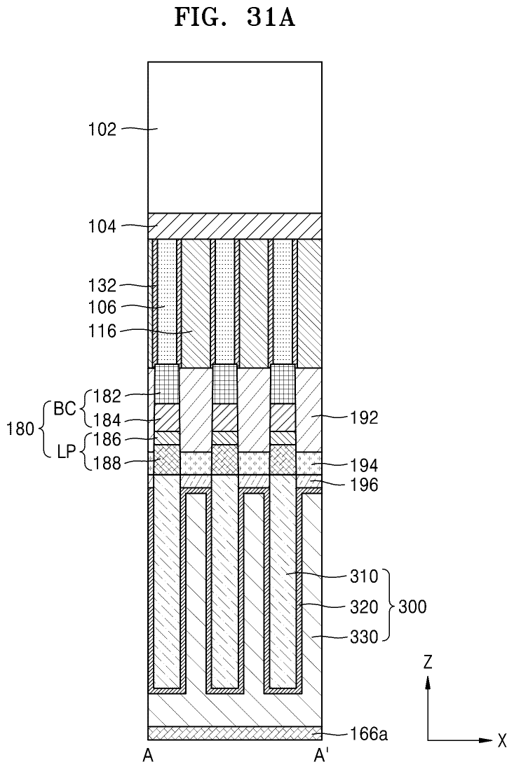

Referring to FIGS. 30A to 30D together, the plurality of capacitor structures 300 penetrating the etch stop film 196 to be electrically connected to the plurality of connection structures 180 are formed. The plurality of capacitor structures 300 may be formed by sequentially stacking the plurality of lower electrodes 310, the capacitor dielectric layer 320, and the upper electrode 330.

A first bonding insulating layer 166a is formed on the upper electrode 330. For example, the first bonding insulating layer 166a may include silicon oxide or SICN.

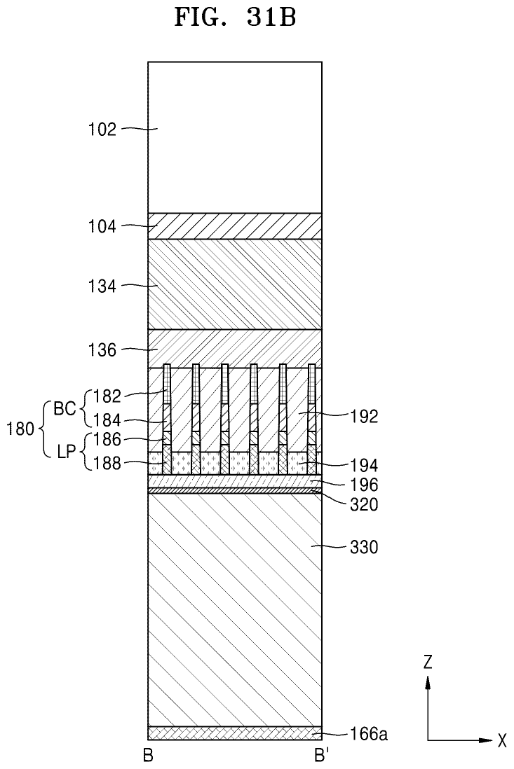

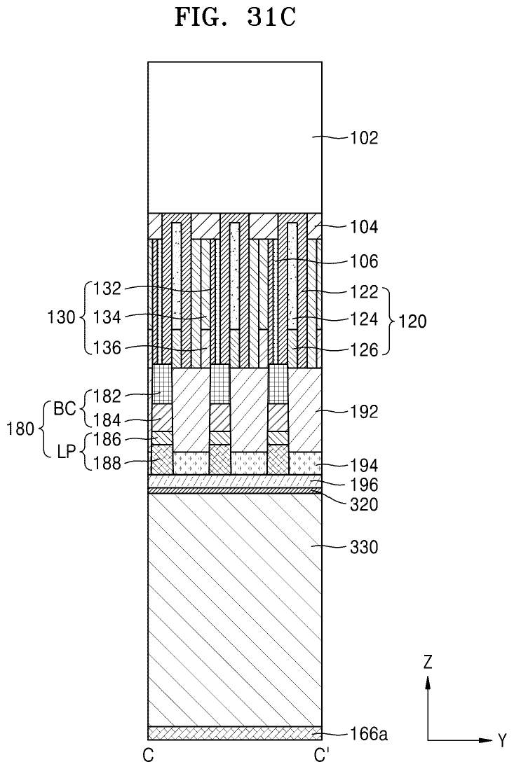

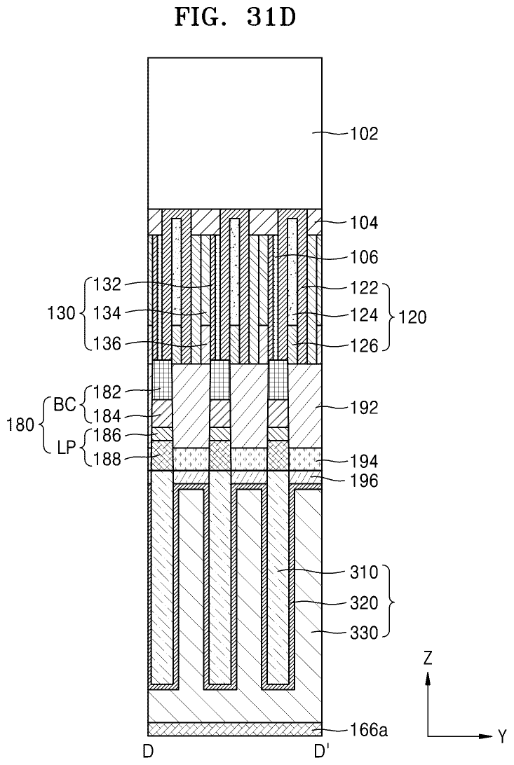

Referring to FIGS. 31A to 31D together, a resultant shown in FIGS. 30A to 30D is turned upside down so that the base substrate 102 is positioned at the upper side, and the first bonding insulating layer 166a is positioned at the lower side.

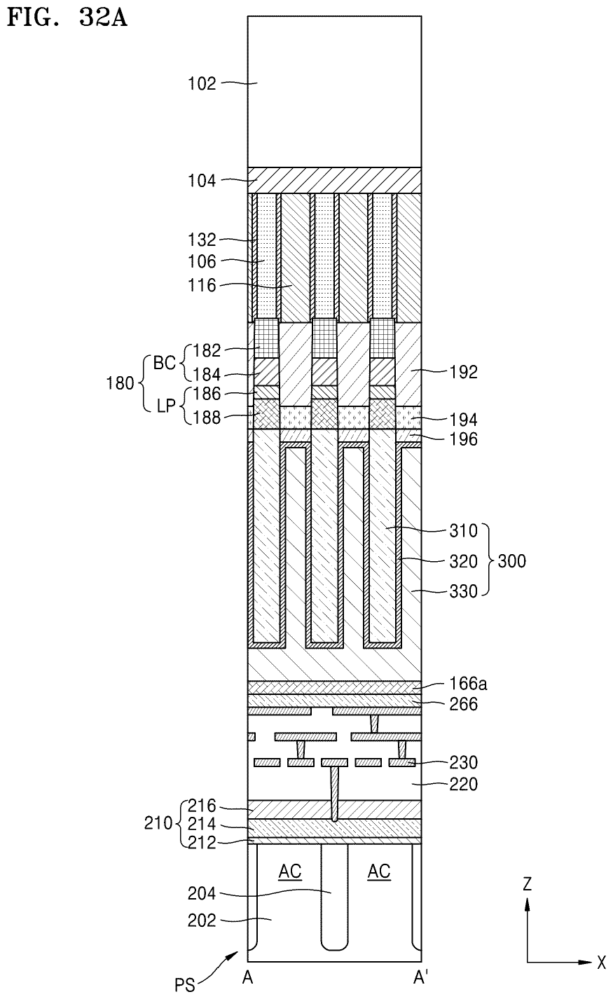

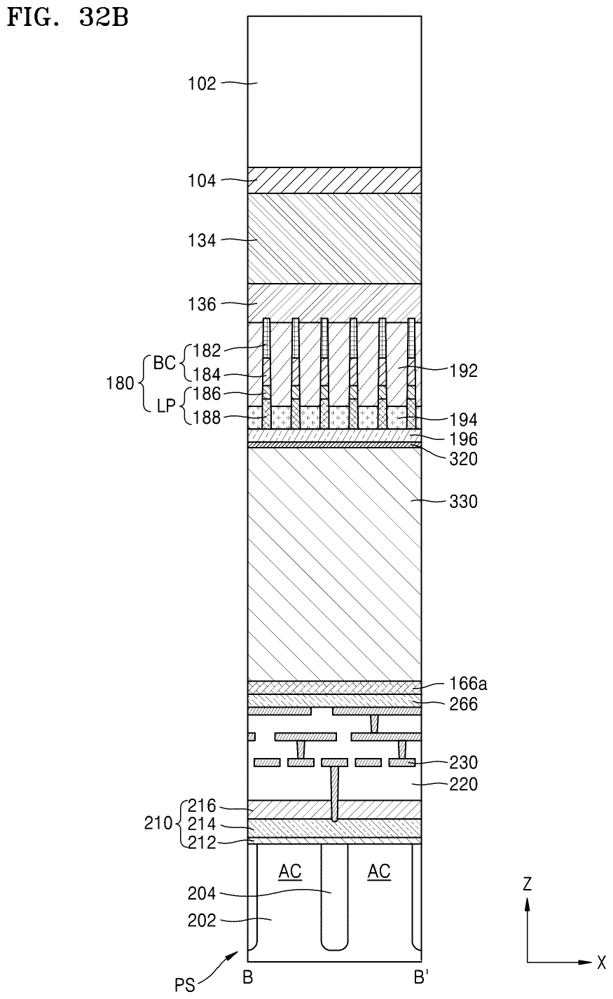

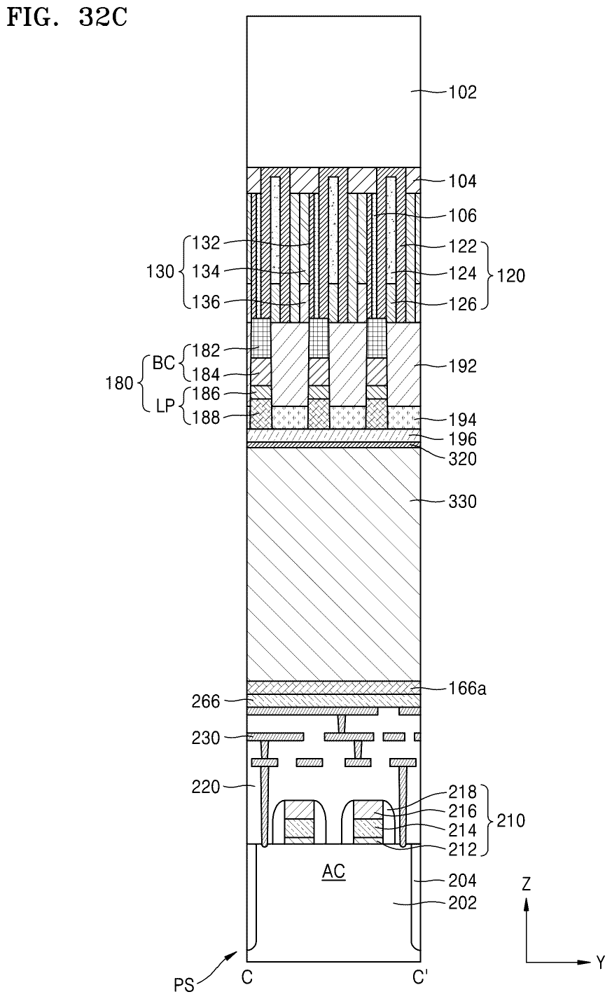

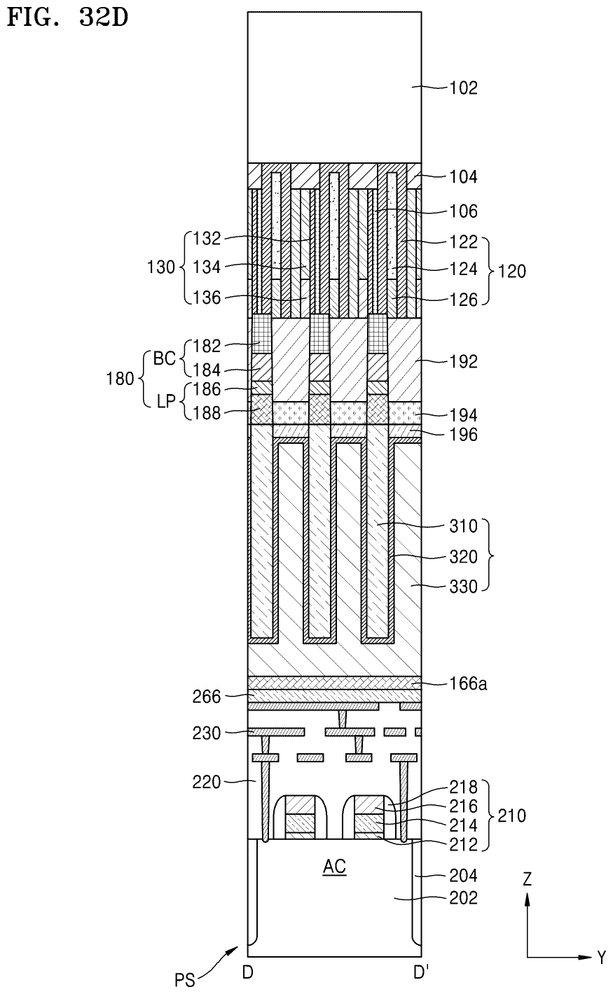

Referring to FIGS. 32A to 32D together, a resultant shown in FIGS. 31A to 31D is bonded to the peripheral circuit structure PS. The peripheral circuit structure PS and the resultant shown in FIGS. 31A to 31D may be bonded to each other by a hybrid bonding method. The second bonding insulating layer 266 and the first bonding insulating layer 166a may be bonded to each other by forming a covalent bond.

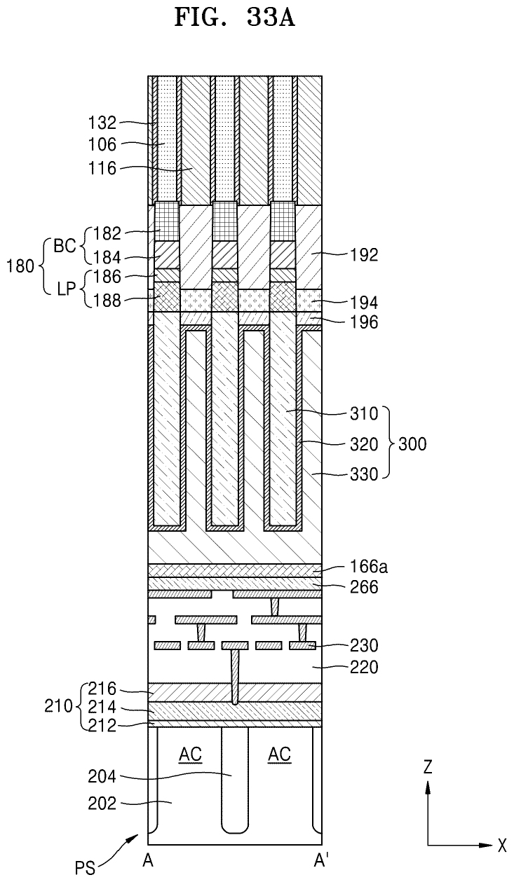

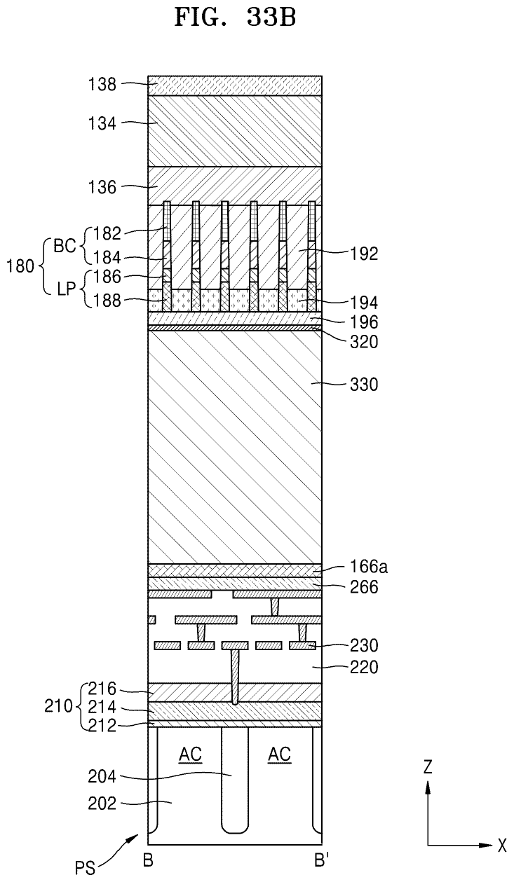

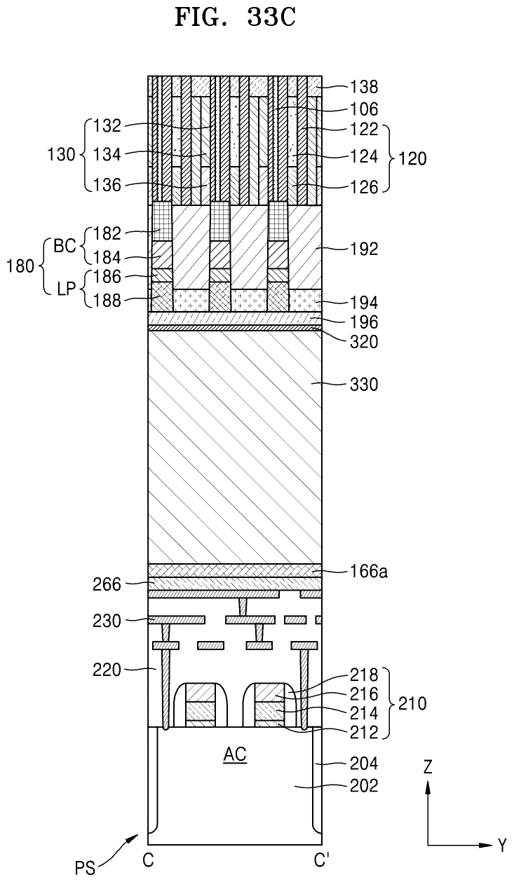

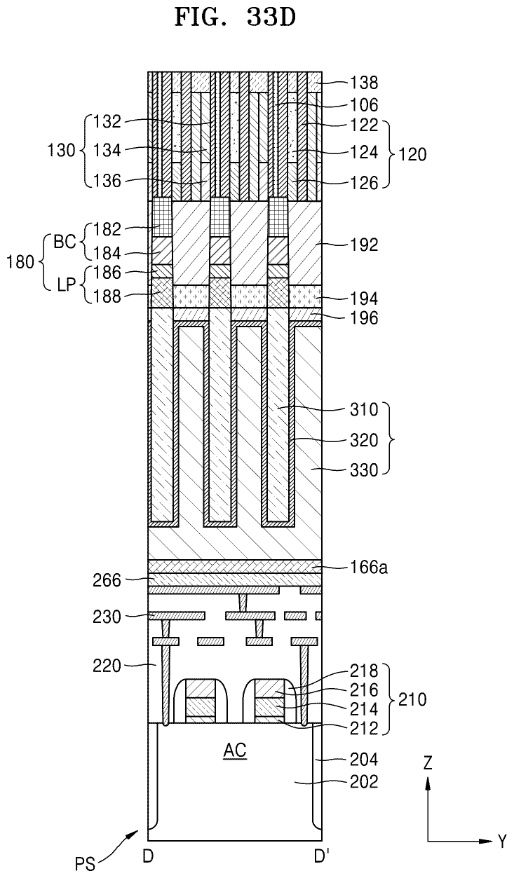

Referring to FIGS. 32A to 32D and 33A to 33D together, the base substrate 102 and the base insulating layer 104 are removed (e.g., etched) to expose the plurality of channel layers 106 and the plurality of word lines 134. In a process of removing the base substrate 102 and the base insulating layer 104, a portion of the plurality of back gate structures 120 may be removed together. For example, in the process of removing the base substrate 102 and the base insulating layer 104, a portion of the plurality of back gate insulating layers 122 may be removed to expose a plurality of back gate lines 124.

Then, after upper portions of the plurality of back gate lines 124 and the plurality of word lines 134 are removed, the buried capping layer 170 filling the upper portions of the plurality of back gate lines 124 and the plurality of word lines 134 is formed.

Referring to FIGS. 34A to 34D together, a bit line structure 140, the plurality of filling insulating layers 152, the cover insulating layer 156, the shield conductive layer 162, and the protective insulating layer 164 may be formed to form a semiconductor memory device 2. In some example embodiments, a protective capping layer 168 may be further formed on the protective insulating layer 164. For example, the protective capping layer 168 may include silicon nitride.

The semiconductor memory device 2 includes the plurality of memory structures such as capacitor structures 300 on the peripheral circuit structure PS, the plurality of connection structures 180 on the plurality of capacitor structures 300, a transistor structure including the plurality of back gate structures 120 on the plurality of connection structures 180, the plurality of word line structures 130, and the plurality of channel layers 106, and the plurality of bit line structures 140 on the transistor structure.

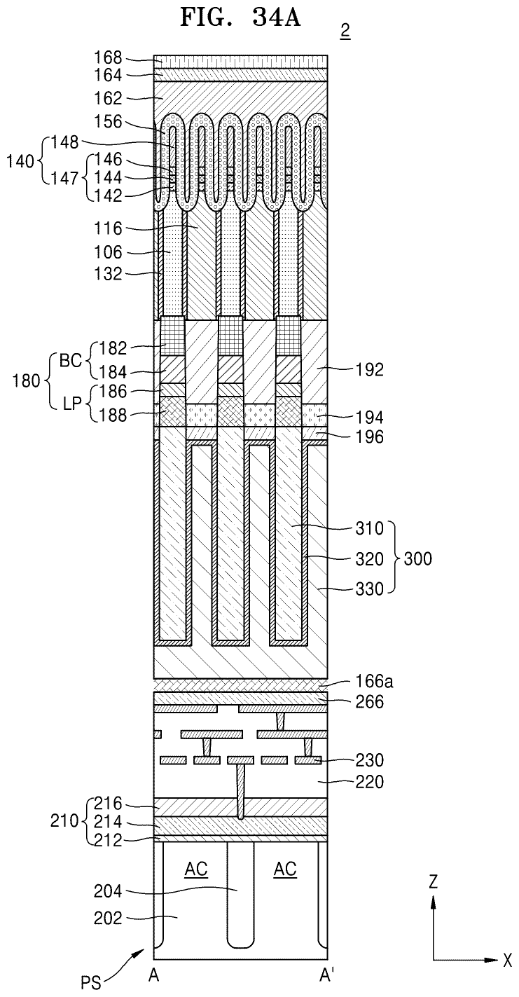

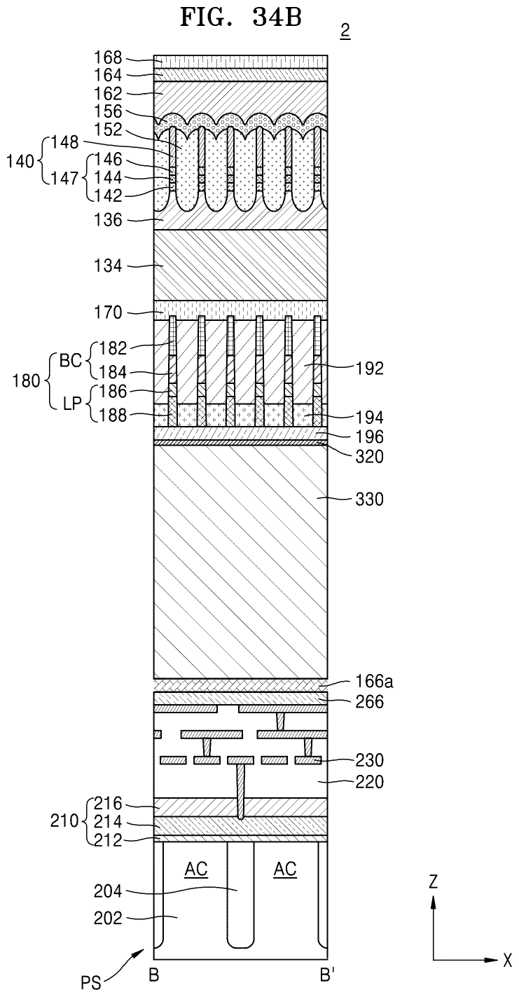

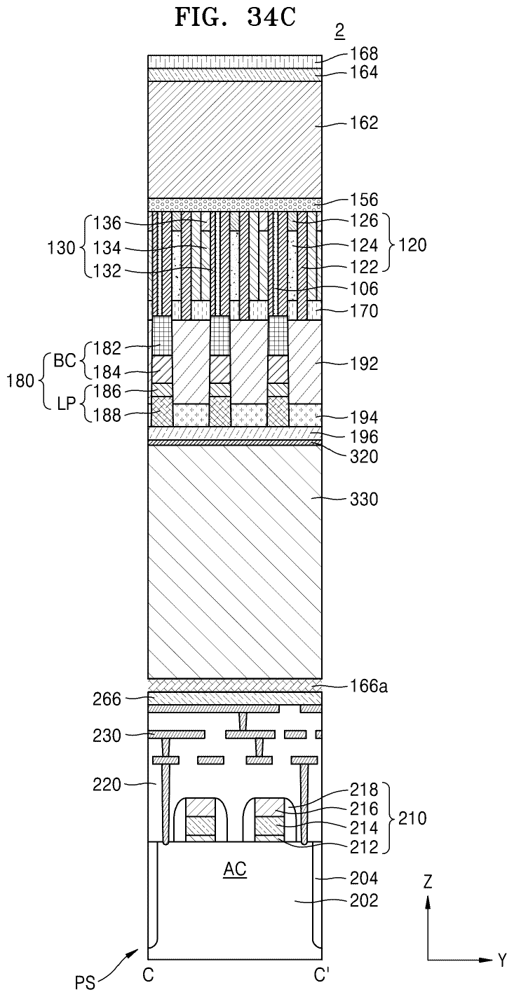

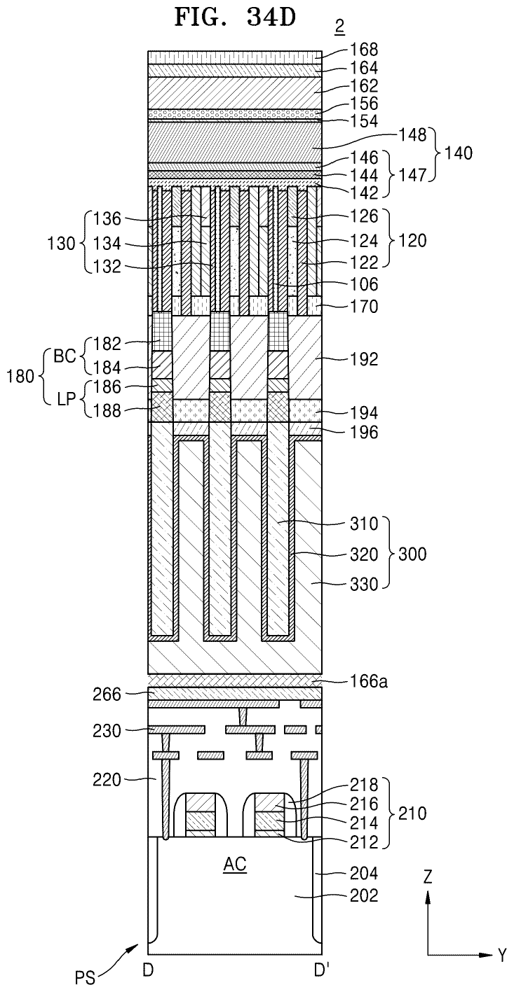

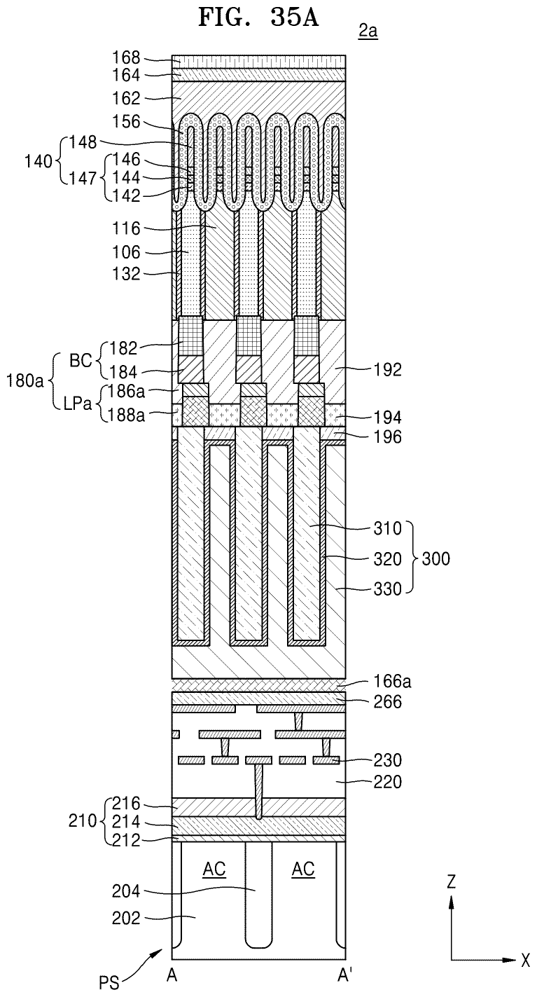

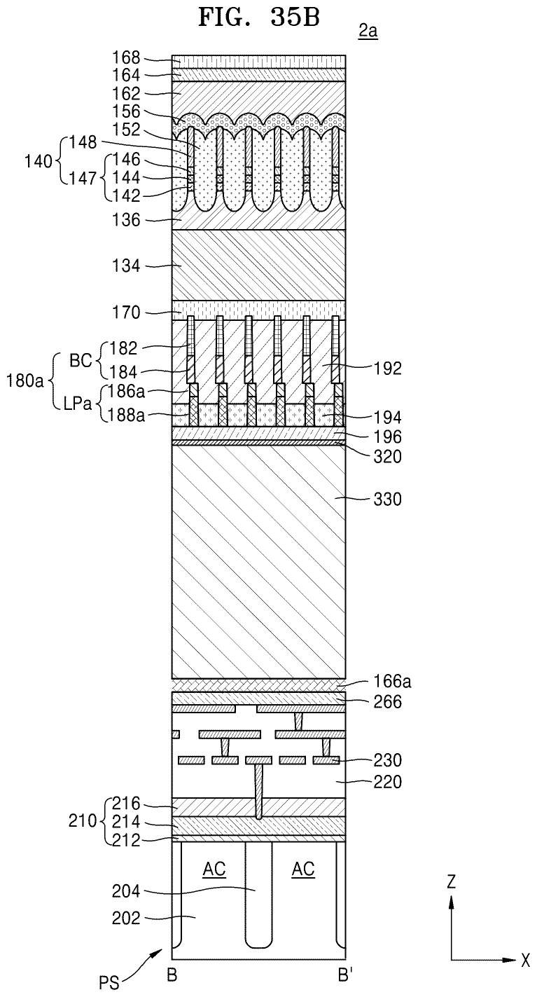

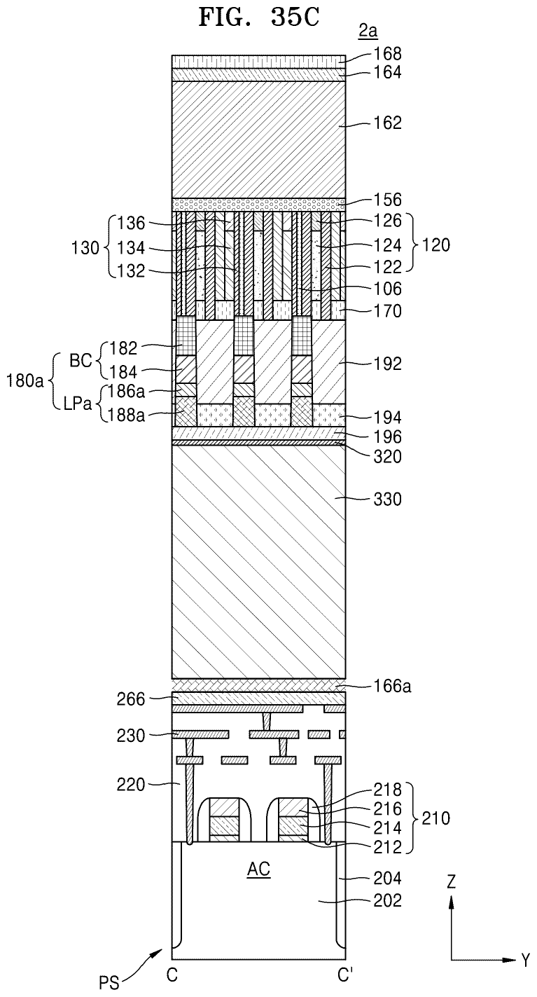

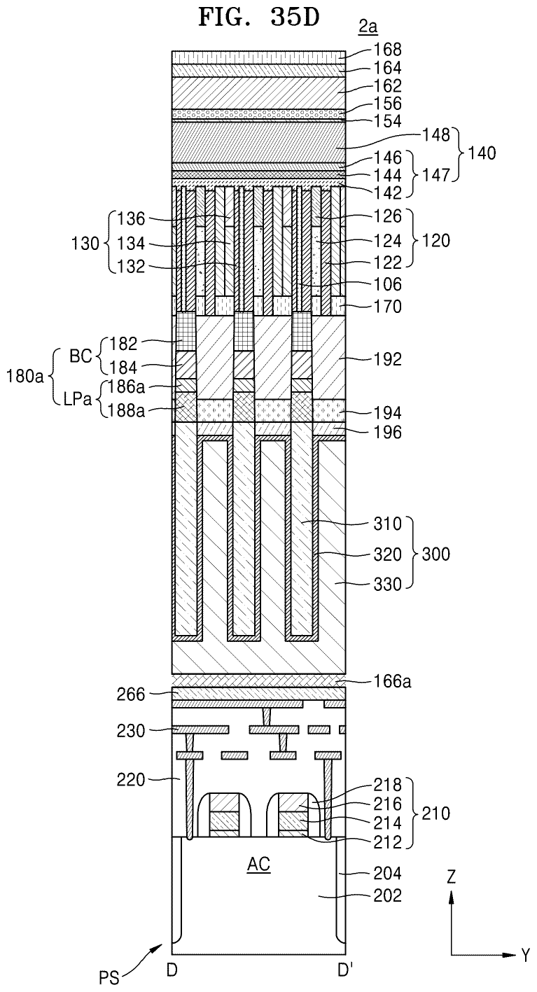

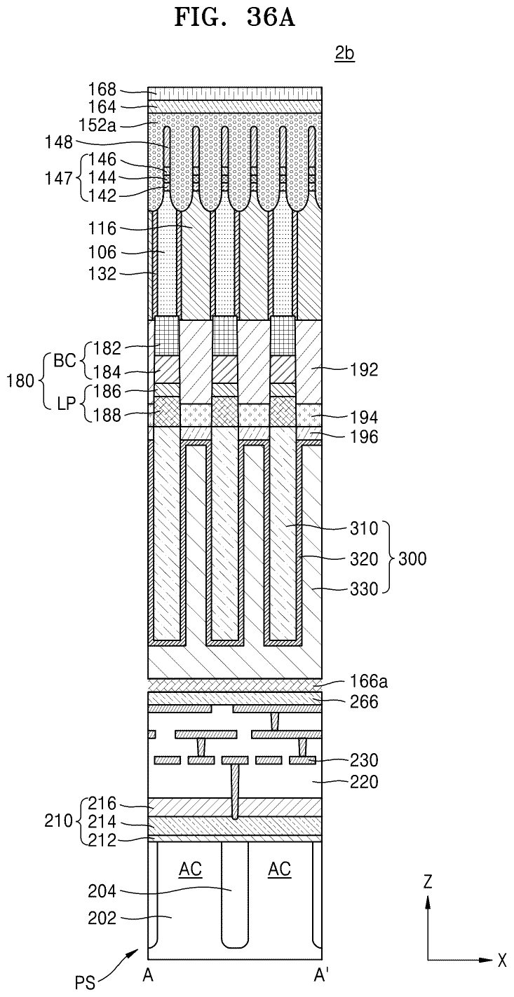

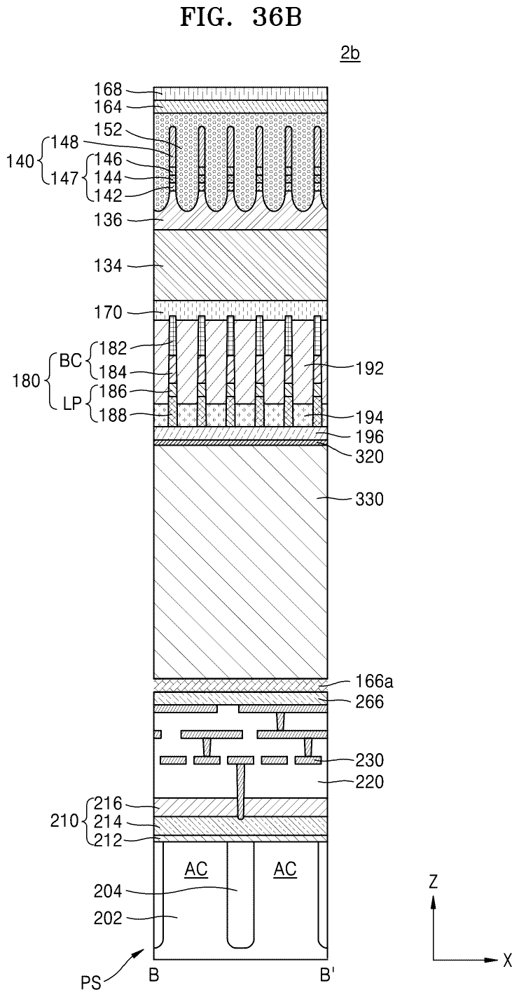

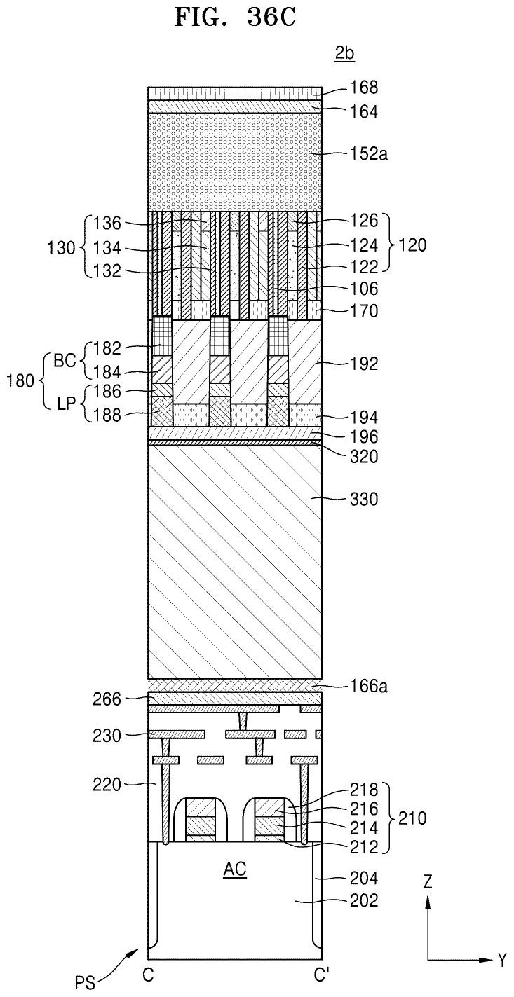

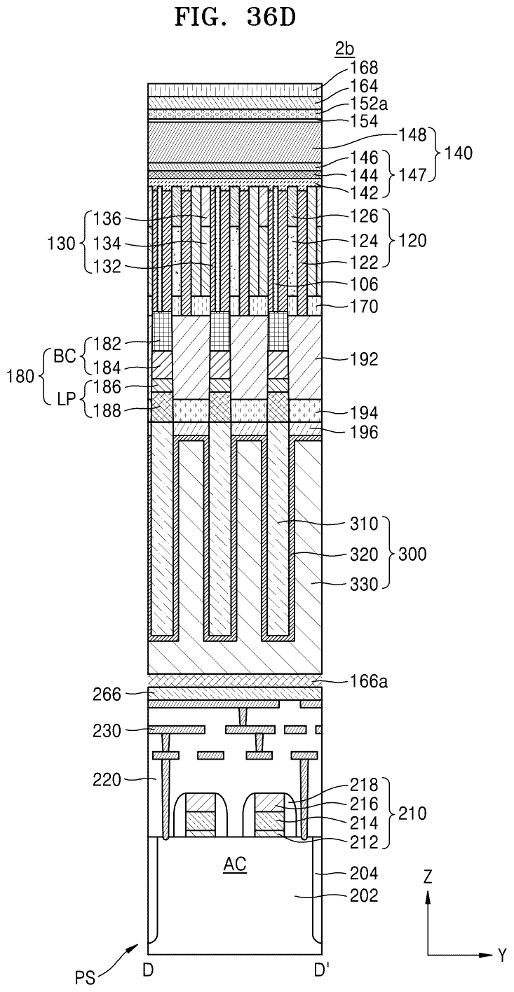

FIGS. 35A to 35D and 36A to 36D are cross-sectional views each illustrating a semiconductor memory device according to various example embodiments. In particular, FIGS. 35A and 36A are cross-sectional views taken along the line A-A′ of FIG. 13, FIGS. 35B and 36B are cross-sectional views taken along the line taken along the line B-B′ of FIG. 13, FIGS. 35C and 36C are cross-sectional views taken along the line C-C′ of FIG. 13, and FIGS. 35D and 36D are cross-sectional views taken along the line D-D′ of FIG. 13.

Referring to FIGS. 35A to 35D together, instead of or in addition to forming the plurality of connection structures 180 shown in FIGS. 34A to 34D, the plurality of connection structures 180a may be formed to form a semiconductor memory device 2a. The plurality of connection structures 180a may be formed with reference to FIGS. 25A to 25D.

Referring to FIGS. 36A to 36D together, instead of or in addition to forming the plurality of filling insulating layers 152, the cover insulating layer 156, and the shield conductive layer 162 shown in FIGS. 34A to 34D, the filling insulating layer 152a filling a portion of each of spaces between the plurality of bit line structures 140 may be formed to form a semiconductor memory device 2b. The filling insulating layer 152a may be formed with reference to FIGS. 27A to 27D.

While inventive concepts have been particularly shown and described with reference to various example embodiments thereof, it will be understood that various changes in form and details may be made therein without departing from the spirit and scope of the following claims. Furthermore, example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a plurality of word lines extending in a first horizontal direction;
a plurality of back gate lines extending in the first horizontal direction and alternately arranged with the plurality of word lines in a second horizontal direction different from the first horizontal direction;
a plurality of channel layers extending in a vertical direction between a word line and a back gate line that are adjacent to each other and are from among the plurality of word lines and the plurality of back gate lines, the plurality of channel layers corresponding to columns in the first horizontal direction;
a plurality of bit lines extending in the second horizontal direction on the plurality of word lines, the plurality of back gate lines, and the plurality of channel layers and electrically connected to the plurality of channel layers; and
a plurality of memory structures comprising a plurality of lower electrodes, an upper electrode on the plurality of lower electrodes, and a dielectric layer between the plurality of lower electrodes and the upper electrode, the plurality of lower electrodes being electrically connected to the plurality of channel layers.

2. The semiconductor memory device of claim 1, wherein the plurality of word lines, the plurality of bit lines, and the plurality of channel layers correspond to a plurality of vertical channel transistors (VCT).

3. The semiconductor memory device of claim 1, further comprising:
a plurality of gate insulating layers between the plurality of word lines and the plurality of channel layers; and
a plurality of back gate insulating layers between the plurality of back gate lines and the plurality of channel layers, covering first and second side surfaces of the plurality of back gate lines, and extending in the first horizontal direction.

4. The semiconductor memory device of claim 3, wherein, in a plan view, the plurality of gate insulating layers surround at least a portion of the plurality of channel layers.

5. The semiconductor memory device of claim 4, wherein one side surface of the plurality of channel layers is covered by the plurality of back gate insulating layers, and remaining side surfaces of the plurality of channel layers are covered by the plurality of gate insulating layers.

6. The semiconductor memory device of claim 1, further comprising:
a peripheral circuit structure comprising a plurality of peripheral circuits,
wherein the plurality of bit lines are between the plurality of channel layers and the peripheral circuit structure.

7. The semiconductor memory device of claim 1, further comprising:
a peripheral circuit structure comprising a plurality of peripheral circuits,
wherein the plurality of memory structures are between the plurality of channel layers and the peripheral circuit structure.

8. The semiconductor memory device of claim 1, further comprising:
a plurality of connection structures including a plurality of lower connection structures arranged toward the plurality of channel layers and electrically connected to the plurality of channel layers, and a plurality of upper connection structures arranged on the plurality of lower connection structures toward the plurality of lower electrodes and electrically connected to the plurality of lower electrodes,
wherein the plurality of lower connection structures and the plurality of upper connection structures corresponding to each other are aligned with each other in the vertical direction.

9. The semiconductor memory device of claim 1, further comprising:
a plurality of connection structures comprising: a plurality of lower connection structures arranged toward the plurality of channel layers and electrically connected to the plurality of channel layers, and a plurality of upper connection structures arranged on the plurality of lower connection structures toward the plurality of lower electrodes and electrically connected to the plurality of lower electrodes,
wherein the plurality of upper connection structures are shifted in a horizontal direction from the plurality of lower connection structures corresponding thereto.

10. The semiconductor memory device of claim 1, wherein,
among the plurality of channel layers, channel layers arranged between a pair of back gate lines among the plurality of back gate lines are arranged in a pair of columns extending in the first horizontal direction, and
the channel layers arranged in the pair of columns between the pair of back gate lines are alternately arranged in the pair of columns in a zigzag manner in the first horizontal direction.

11. A semiconductor memory device comprising:
a plurality of word line structures comprising a plurality of word lines and a plurality of gate insulating layers covering the plurality of word lines, the plurality of word lines extending in a first horizontal direction and having a constant width in a second horizontal direction orthogonal to the first horizontal direction;
a plurality of back gate structures comprising a plurality of back gate lines extending in the first horizontal direction and a plurality of back gate insulating layers covering the plurality of back gate lines and arranged between the plurality of word line structures;
a plurality of channel layers extending in a vertical direction between a word line structure and a back gate line structure adjacent to each other in the second horizontal direction among the plurality of word line structures and the plurality of back gate structures, to correspond to a column in the first horizontal direction;
a device isolation film between a word line and a back gate insulating layer adjacent to each other among the plurality of word lines and the plurality of back gate insulating layers;
a plurality of bit lines electrically connected to the plurality of channel layers and extending in the second horizontal direction on a transistor structure comprising the plurality of word line structures, the plurality of back gate structures, and the plurality of channel layers; and
a plurality of memory structures comprising a plurality of lower electrodes, an upper electrode on the plurality of lower electrodes, and a dielectric layer between the plurality of lower electrodes and the upper electrode, the plurality of lower electrodes being electrically connected to the plurality of channel layers.

12. The semiconductor memory device of claim 11, wherein the device isolation film fills a space between two gate insulating layers surrounding two channel layers adjacent to each other in the first horizontal direction among the plurality of channel layers, the two gate insulating layers being from among the plurality of gate insulating layers.

13. The semiconductor memory device of claim 11, wherein each of the plurality of bit lines is electrically connected to a different one of the plurality of channel layers, the channel layers being arranged between a pair of back gate lines among the plurality of back gate lines to be arranged in a pair of columns extending in the first horizontal direction.

14. The semiconductor memory device of claim 13, wherein the channel layers arranged to correspond to the pair of columns are alternately arranged in the pair of columns in the first horizontal direction.

15. The semiconductor memory device of claim 11, further comprising:
a peripheral circuit structure comprising a plurality of peripheral circuits,
wherein the transistor structure is between the plurality of memory structures and the peripheral circuit structure.

16. The semiconductor memory device of claim 11, further comprising:
a peripheral circuit structure comprising a plurality of peripheral circuits,
wherein the plurality of memory structures are between the transistor structure and the peripheral circuit structure.

17. The semiconductor memory device of claim 11, further comprising:
a cover insulating layer covering the plurality of bit lines; and
a shield conductive layer covering the cover insulating layer and filling spaces between the plurality of bit lines.

18. A semiconductor memory device comprising:
a peripheral circuit structure comprising a plurality of peripheral circuits;
a plurality of word line structures arranged on the peripheral circuit structure and comprising a plurality of word lines and a plurality of gate insulating layers covering the plurality of word lines, the plurality of word lines extending in a first horizontal direction and having a constant width in a second horizontal direction orthogonal to the first horizontal direction;
a plurality of back gate structures arranged on the peripheral circuit structure and comprising a plurality of back gate lines and a plurality of back gate insulating layers covering the plurality of back gate lines, the plurality of back gate lines being alternately arranged with the plurality of word lines in the second horizontal direction and extending in the first horizontal direction;
a plurality of channel layers extending in a vertical direction between a word line structure and a back gate line structure adjacent to each other in the second horizontal direction among the plurality of word line structures and the plurality of back gate structures, to correspond to a column in the first horizontal direction;
a device isolation film between a word line and a back gate insulating layer adjacent to each other among the plurality of word lines and the plurality of back gate insulating layers;
a plurality of bit lines extending in the second horizontal direction on the plurality of word line structures, the plurality of back gate structures, and the plurality of channel layers and electrically connected to one end of the plurality of channel layers in a vertical direction; and
a plurality of memory structures comprising a plurality of lower electrodes, an upper electrode on the plurality of lower electrodes, and a dielectric layer between the plurality of lower electrodes and the upper electrode, the plurality of lower electrodes being electrically connected to another end of the plurality of channel layers in the vertical direction,
wherein the plurality of word lines, the plurality of bit lines, and the plurality of channel layers correspond to a plurality of vertical channel transistors.

19. The semiconductor memory device of claim 18, wherein the plurality of channel layers and the plurality of bit lines are between the plurality of memory structures and the peripheral circuit structure.

20. The semiconductor memory device of claim 18, wherein the plurality of channel layers and the plurality of memory structures are between the plurality of bit lines and the peripheral circuit structure.
